(19) United States
(12) Patent Application Publication
(10) Pub. No.: US 2017/0317214 A1
(43) Pub. Date: Nov. 2, 2017

(54) SEMICONDUCTOR DEVICE

(71) Applicant: SAMSUNG ELECTRONICS CO., LTD., Suwon-si (KR)

(72) Inventors: Toshiro NAKANISHI, Seongnam-si (KR); Kab Jin NAM, Seoul (KR); Lijie ZHANG, Suwon-si (KR)

(73) Assignee: SAMSUNG ELECTRONICS CO., LTD., Suwon-si (KR)

(21) Appl. No.: 15/370,182

(22) Filed: Dec. 6, 2016

(30) Foreign Application Priority Data
May 2, 2016 (KR) 10-2016-0053978

(51) Int. Cl. H01L 29/78; H01L 29/10

(52) U.S. Cl. CPC H01L 29/7853; H01L 29/1037

(57) ABSTRACT

A semiconductor device is provided. The semiconductor device includes a drain region and a source region spaced apart from each other, a semiconductor pattern disposed between the drain region and the source region and comprising a first region and a second region, wherein a thickness of the first region is larger than a thickness of the second region, and the first region is disposed between the drain region and the second region, and a gate electrode intersecting the semiconductor pattern.

### CROSS-REFERENCE TO RELATED APPLICATION

This application claims priority from Korean Patent Application No. 10-2016-0053978 filed on May 2, 2016 in the Korean Intellectual Property Office, the disclosure of which is incorporated herein by reference in its entirety.

### BACKGROUND

### 1. Technical Field

Apparatuses and methods consistent with exemplary embodiments relate to a semiconductor device.

### 2. Description of the Related Art

Recently, semiconductor devices are becoming smaller with higher performance. Accordingly, even small structural difference in a transistor included in a semiconductor device results in great influence on the performance of the semiconductor device. As one of the scaling technologies to increase density of semiconductor devices, multi-gate transistors have been proposed in which a silicon body having a fin- or nanowire-shape is formed on a substrate, and gates are formed on a surface of the silicon body.

Because the multi-gate transistor utilizes a three-dimensional channel, scaling is facilitated. In addition, electric current control ability can be enhanced without increasing lengths of the gates of the multi-gate transistor. Further, the short-channel effect (SCE) that refers to the influence on electric potential in channel region by a drain voltage can be effectively suppressed.

Incidentally, as the channel becomes thinner, self-heating or ionization occurs more often. As a result, reliability of semiconductor devices may be degraded.

### SUMMARY

One or more exemplary embodiments provide a semiconductor device capable of improving the reliability by way of adjusting the thickness of a channel region adjacent to the drain.

The objectives addressed by the exemplary embodiments may not be limited to those mentioned above, and accordingly, other objectives that are not mentioned herein would be clearly understandable to those skilled in the art based on the description provided below

According to an aspect of an exemplary embodiment, there is provided a semiconductor device including a drain region and a source region spaced apart from each other, a semiconductor pattern disposed between the drain region and the source region and comprising a first region and a second region, wherein a thickness of the first region is larger than a thickness of the second region, and the first region is disposed between the drain region and the second region, and a gate electrode intersecting the semiconductor pattern.

According to an aspect of another exemplary embodiment, there is provided a semiconductor device including a substrate, a field insulation film on the substrate, a semiconductor pattern protruding from the substrate and comprising a first region and a second region, wherein a part of the semiconductor pattern protrudes from an upper surface of the field insulation film, a source region and a drain region disposed on the substrate and on both sides of the semiconductor pattern, respectively, and a gate electrode intersecting the semiconductor pattern, wherein a first region of the semiconductor pattern is disposed between the semiconductor pattern and the second region, and a thickness of a first region of the semiconductor pattern is larger than a thickness of a second region of the semiconductor pattern.

According to an aspect of another exemplary embodiment, there is provided a semiconductor device including a drain region and a source region spaced apart from each other, a channel region disposed between the drain region and the source region, and a gate electrode intersecting the semiconductor pattern, wherein a thickness of a region of the channel region adjacent to the drain region is larger than a thickness of a region of the channel region adjacent to the source region.

### BRIEF DESCRIPTION OF THE DRAWINGS

The above and other aspects and features will become more apparent from the following detailed description with reference to the accompanying drawings, in which:

FIG. 1 is a perspective view of a semiconductor device according to an exemplary embodiment;

FIG. 2 is a cross-sectional view taken along line A-A′ of FIG. 1;

FIG. 3 is a perspective view of a semiconductor device according to an exemplary embodiment;

FIG. 4 is a cross-sectional view taken along line A-A′ of FIG. 1;

FIG. 5 is a cross-sectional view taken along line B-B′ of FIG. 1;

FIG. 6 is an enlarged view of area K of FIG. 5;

FIG. 7 is a cross-sectional view taken along line B-B′ of FIG. 1;

FIG. 8 is a cross-sectional view taken along line B-B′ of FIG. 1;

FIG. 9 is an enlarged view of area L shown in FIG. 8;

FIGS. 10 to 15 are cross-sectional views of a semiconductor device according to exemplary embodiments;

FIGS. 16 to 23 are cross-sectional views taken along line C-C′ of FIG. 1;

FIGS. 24 to 32 are cross-sectional views of a semiconductor device according to exemplary embodiments;

FIG. 33 is an enlarged view of area M shown in FIG. 32;

FIGS. 34 to 44 are cross-sectional views of a semiconductor device according to exemplary embodiments; and

FIG. 45 is a block diagram of a system on chip (SoC) system including a semiconductor device according to an exemplary embodiment.

### DETAILED DESCRIPTION OF THE EXEMPLARY EMBODIMENTS

Exemplary embodiments will now be described more fully hereinafter with reference to the accompanying drawings. The exemplary embodiments may, however, be embodied in different forms and should not be construed as limited to the exemplary embodiments set forth herein. Rather, these exemplary embodiments are provided so that this disclosure will be thorough and complete, and will fully convey the scope of the inventive concept to those skilled in the art. The same reference numbers indicate the same components throughout the specification. In the attached figures, the thickness of layers and regions is exaggerated for clarity.

It will be understood that when an element or layer is referred to as being “connected to,” or “coupled to” another element or layer, it can be directly connected to or coupled to another element or layer or intervening elements or layers may be present. In contrast, when an element or layer is referred to as being “directly connected to” or “directly coupled to” another element or layer, there are no intervening elements or layers present. As used herein, the term “and/or” includes any and all combinations of one or more of the associated listed items.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the inventive concept.

The use of the terms “a” and “an” and “the” and similar referents in the context of describing the exemplary embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted.

Unless defined otherwise, all technical and scientific terms used herein have the same meaning as commonly understood by one of ordinary skill in the art to which the exemplary embodiments belong. It is noted that the use of any and all examples, or exemplary terms provided herein is intended merely to better illuminate the exemplary embodiments and is not a limitation on the scope of the exemplary embodiments unless otherwise specified. Further, unless defined otherwise, all terms defined in generally used dictionaries may not be overly interpreted.

Exemplary embodiments will be described with reference to perspective views, cross-sectional views, and/or plan views. Thus, the profile of an exemplary view may be modified according to manufacturing techniques and/or allowances. That is, the exemplary embodiments are not intended to limit the scope but cover all changes and modifications that can be caused due to a change in manufacturing process. Thus, regions shown in the drawings are illustrated in schematic form and the shapes of the regions are presented simply by way of illustration and not as a limitation.

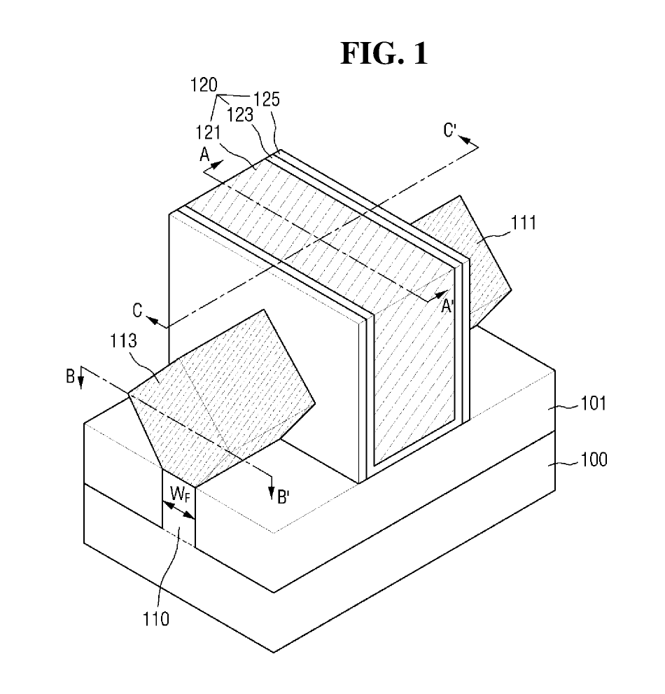

Hereinafter, a semiconductor device according to exemplary embodiments will be described with reference to FIGS. 1 to 4.

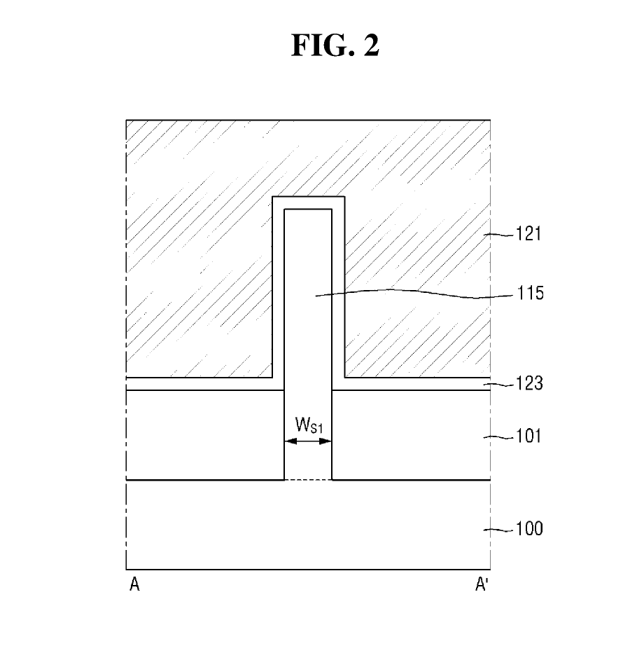

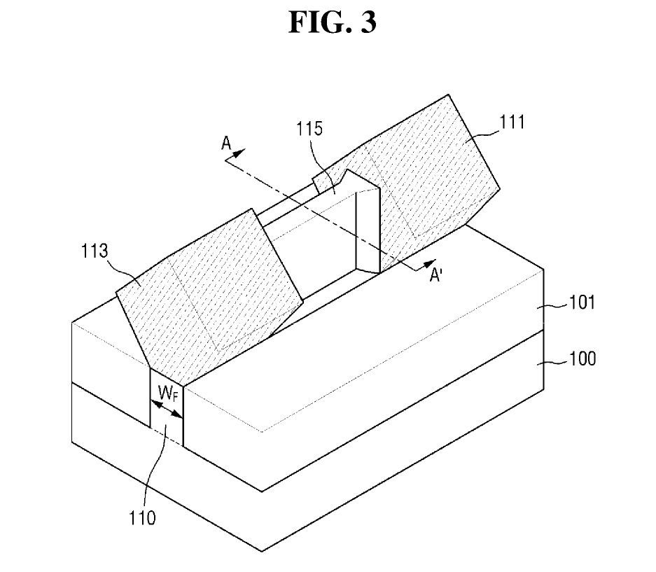

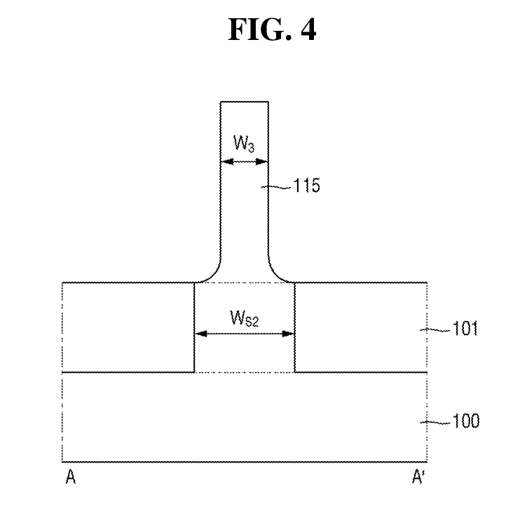

FIG. 1 is a perspective view of a semiconductor device according to an exemplary embodiment. FIG. 2 is a cross-sectional view taken along line A-A′ of FIG. 1. FIG. 3 is a perspective view of a semiconductor device according to an exemplary embodiment. FIG. 4 is a cross-sectional view taken along line A-A′ of FIG. 1.

Referring to FIGS. 1 and 2, a semiconductor device according to an exemplary embodiment may include a field insulation film 101, a fin-like pattern 110, a drain region 111, a source region 113, a semiconductor pattern 115, and a gate structure 120 on a substrate 100.

The substrate 100 may be, for example, a bulk silicon substrate or a SOI (silicon-on-insulator) substrate. Alternatively, the substrate 100 may be a silicon substrate or a substrate made of other materials, such as silicon germanium (SiGe), indium antimonide (InSb), lead-telluride (PbTe) compound, indium arsenide (InAs), indium phosphide (InP), gallium arsenide (GaAs) and gallium antimonide (GaSb). Alternatively, the substrate 100 may be formed by growing an epitaxial layer on a base substrate.

The field insulation film 101 may be formed on the substrate 100. The field insulation film 101 may surround at least a part of side walls of the fin-like pattern 110.

Although the side walls of the fin-like pattern 110 shown in FIG. 1 is completely surrounded by the field insulation film 101 for the convenience of illustration, it is merely illustrative. For example, only a part of the side walls of the fin-like pattern 110 may be surrounded by the field insulation film 101.

The fin-like pattern 110 may be formed on the substrate 100. The fin-like pattern 110 may protrude from the upper surface of the substrate 100. The fin-like pattern 110 may be defined by the field insulation film 101.

The field insulation film 101 may be made of a material including at least one of a silicon oxide film, a silicon nitride film and a silicon oxynitride film.

The fin-like pattern 110 may be disposed on either side of the semiconductor pattern 115.

The fin-like pattern 110 may include silicon or germanium, which are single-element semiconductor materials. Alternatively, the fin-like pattern 110 may include a compound semiconductor, such as a IV-IV group compound semiconductor or a III-V group compound semiconductor.

As examples of the group IV-IV compound semiconductor, an epitaxial layer may include a binary compound or a ternary compound containing at least two of carbon (C), silicon (Si), germanium (Ge) and tin (Sn), or such a compound doped with a group IV element.

As examples of the group III-V compound semiconductor, the epitaxial layer may include a binary compound, a ternary compound or a quaternary compound consisting of at least one of aluminum (Al), gallium (Ga) and indium (In) as the group III element and one of phosphorous (P), arsenic (As) and antimony (Sb) as the group V element.

In the exemplary embodiment, the drain region 111 and the source region 113 may be formed on the substrate 100. The drain region 111 and the source region 113 may be formed on, for example, the fin-like pattern 110. The drain region 111 may be spaced apart from the source region 113. The drain region 111 and the source region 113 may be connected to each other by the semiconductor pattern 115. The drain region 111 and the source region 113 may be disposed on both sides of the semiconductor pattern 115, respectively.

If a transistor is a PMOS transistor, the drain region 111 and the source region 113 may include a compressive stress material. For example, the compressive stress material may be a material having a lattice constant larger than that of Si, such as SiGe. The compressive stress material may improve mobility of carriers in a channel region by exerting compressive stress to the drain region 111 and the source region 113.

If a transistor is a NMOS transistor, the drain region 111 and the source region 113 may be made of the same material as the substrate 110 or may be made of a tensile stress material. For example, if the substrate 100 is made of Si, the drain region 111 and the source region 113 may be made of Si or may be made of a material having a lattice constant smaller than that of Si (e.g., SiC).

The drain region 111 and the source region 113 may be in-situ doped with impurities during an epitaxial process for forming the drain region 111 and the source region 113, if necessary.

The drain region 111 and the source region 113 may have at least one of a diamond shape, a circle shape and a rectangular shape. Although the drain region 111 and the source region 113 have a diamond shape (a pentagon shape or a hexagonal shape) in FIG. 1, the shape is not limited thereto.

The semiconductor pattern 115 may be formed between the drain region 111 and the source region 113. The semiconductor pattern 115 may be a channel region, for example.

One end of the semiconductor pattern 115 may be connected to the drain region 111, and other end of the semiconductor pattern 115 may be connected to the source region 113.

The semiconductor pattern 115 may be extended in parallel with the fin-like pattern 110. In other words, the semiconductor pattern 115 may be extended such that it intersects a gate structure 120.

The semiconductor pattern 115 may protrude from the substrate 100. A part of the semiconductor pattern 115 may protrude from the upper surface of the field insulation film 101. The field insulation film 101 may surround at least a part of the semiconductor pattern 115, for example.

A thickness Ws1 of the portion of the semiconductor pattern 115 that is surrounded by the field insulation film 101 may be different from a thickness Wf of the fin-like pattern 110 disposed under the drain region 111 or the source region 113. In an exemplary embodiment, the thickness Ws1 of the portion of the semiconductor pattern 115 that is surrounded by the field insulation film 101 may be smaller than the thickness Wf of the fin-like pattern 110 disposed under the drain region 111 or the source region 113. The thicknesses may be measured in the direction in which the gate structure 120 is extended.

The gate structure 120 may intersect the semiconductor pattern 115. The gate structure 120 may be formed between the drain region 111 and the source region 113. In other words, the drain region 111 and the source region 113 may be formed on both sides of the gate structure 120, respectively. The gate structure 120 may be extended such that it intersects the semiconductor pattern 115. The gate structure 120 may include a gate electrode 121, a gate insulation film 123, a gate spacer 125.

The gate electrode 121 may intersect region II of the semiconductor pattern 115. A detailed description thereon will be made below.

The gate structure 121 may include a conductive material. Although the gate electrode 121 is shown as a single layer, it is merely illustrative. For example, the gate electrode 121 may include a work function conductive layer that adjusts work function, and a filling conductive layer that fills space created by the work function conductive layer.

The gate electrode 121 may include at least one of TiN, WN, TaN, Ru, TiC, TaC, Ti, Ag, Al, TiAl, TiAlN, TiAlC, TaCN, TaSiN, Mn, Zr, W, and Al, for example. Alternatively, the gate structure 121 may be made of Si, SiGe, etc., which is not metal. The gate electrode 121 may be formed via, but is not limited to, a replacement process.

The gate insulation layer 123 may be formed on side walls of the gate electrode 121 and between the gate electrode 121 and the field insulation film 101. In addition, the gate insulation film 123 may be formed on a portion of the side walls of the semiconductor pattern 115 that protrudes from the upper surface of the field insulation film 101 and on the upper surface of the semiconductor pattern 115.

Although not shown in the drawings, an interface film may be formed between the gate insulation film 123 and the semiconductor pattern 115. In addition, the interface film may conform to the profile of the gate insulation film 123 depending on a method of forming the interface film.

The gate insulation film 123 may include at least one of silicon oxide, silicon oxynitride, silicon nitride and a high-k material having a dielectric constant greater than that of silicon oxide.

For example, the high-k material may include at least one of: hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

The high-k material insulation film is not limited thereto, and the high-k material insulation film may include metal nitride (e.g., hafnium nitride) and/or oxynitride (hafnium oxynitride).

The gate spacer 125 may be formed between the drain region 111 and the gate electrode 121 and between the source region 113 and the gate electrode 121, for example. However, this is merely illustrative. In some processing, at least a part of the gate spacer 125 may be formed on the drain region 111 and the source region 113. The gate spacer 125 may be extended in the same direction as the gate electrode 121 is extended.

Although the gate spacer 125 is shown as having a single film structure, this is merely illustrative. The gate spacer 125 may have a multi-film structure, for example.

The gate spacer 125 may have, but is not limited to, a rectangular shape. For example, the gate spacer 125 may have a variety of shapes depending on processing.

The gate spacer 125 may include at least one of silicon nitride (SiN), silicon oxynitride (SiON), silicon oxide (SiO2), silicon oxycarbonitride (SiOCN), and a combination thereof.

Hereinafter, a semiconductor device according to an exemplary embodiment will be described with reference to FIGS. 1, 3 and 4. For clarity of illustration, the redundant description will be omitted.

FIG. 3 is a perspective view of a semiconductor device according to an exemplary embodiment, in which the gate structure 120 shown in FIG. 1 is removed from the device for clarity of illustration. FIG. 4 is a cross-sectional view taken along line A-A′ of FIGS. 1 and 3.

Referring to FIGS. 1, 3 and 4, unlike FIG. 2, the thickness Ws2 of the portion of the semiconductor pattern 115 that is surrounded by the field insulation film 101 may be substantially equal to the thickness Wf of the fin-like pattern 110 disposed under the drain region 111 or the source region 113. In other words, the distribution of the thickness of the portion of the semiconductor pattern 115 that is surrounded by the field insulation film 101 may be substantially equal to the thickness of the fin-like pattern 110 disposed under the drain region 111 or the source region 113.

For example, when a gate-last process is performed, only a portion of the semiconductor pattern 115 that protrudes from the upper surface of the field insulation film 101 may be patterned. In this case, the thickness Ws2 of the portion of the semiconductor pattern 115 that is surrounded by the field insulation film 101 may be larger than a thickness W3 of the portion of the semiconductor pattern 115 that protrudes from the top surface of the field insulation film 101 to be patterned.

Hereinafter, a semiconductor device according to exemplary embodiments will be described with reference to FIGS. 1, 5 and 6. For clarity of illustration, the redundant description will be omitted.

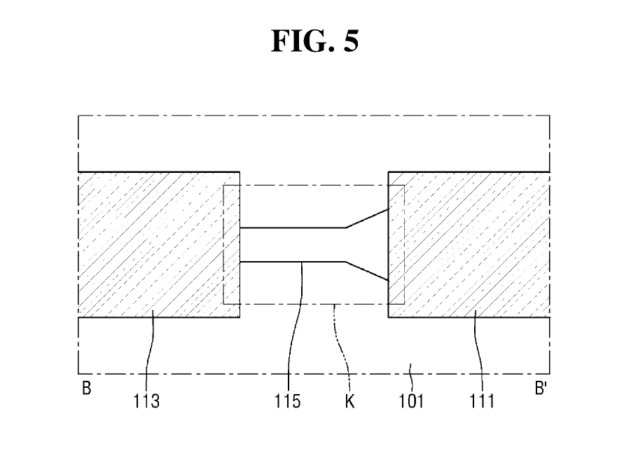

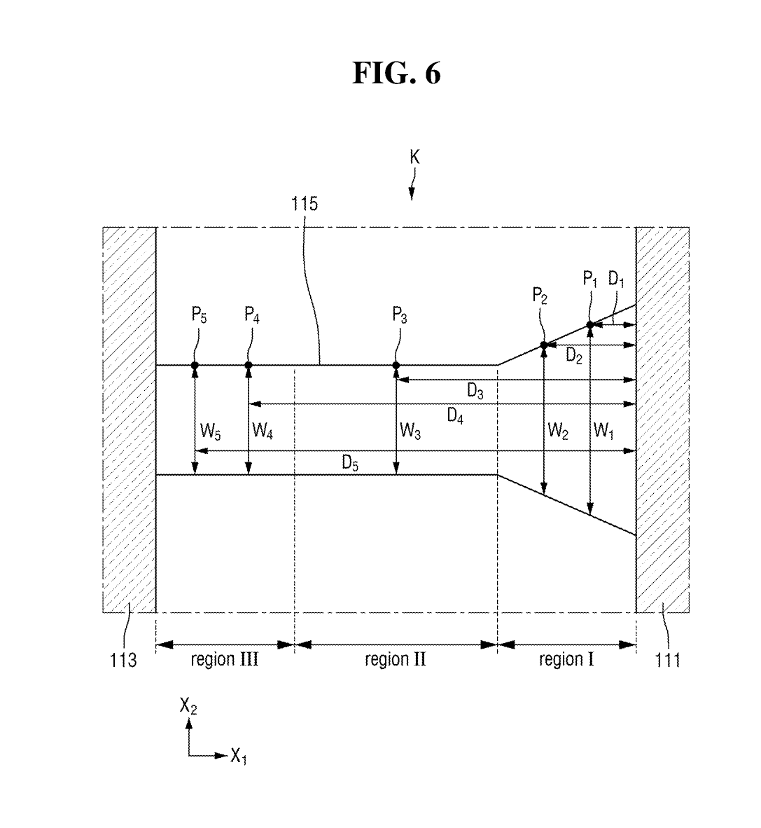

FIG. 5 is a cross-sectional view taken along line B-B′ of FIG. 1. FIG. 6 is an enlarged view of area K of FIG. 5. In FIGS. 5 and 6, the gate structure 120 and the like are not shown for clarity of illustration.

Referring to FIGS. 1, 5 and 6, the semiconductor pattern 115 may include region I, region II and region III.

The region II may be disposed between region I and region III. The region I may be disposed between the drain region 111 and region II. The region III may be disposed between the source region 113 and region II.

The region I may be disposed closer to the drain region 111 than the region III is. The region III may be disposed more distant from the drain region 111 than the region I is.

The region I of the semiconductor pattern 115 may include a first position P1 that is spaced apart from the drain region 111 by a first distance D1. The thickness of the region I of the semiconductor pattern 115 at the first position P1 may be W1.

The region I of the semiconductor pattern 115 may include a second position P2 that is spaced apart from the drain region 111 by a second distance D2. The second distance D2 may be larger than the first distance D1. The thickness of the region I of the semiconductor pattern 115 at the second position P2 may be W2.

In an exemplary embodiment, the thicknesses of region I of the semiconductor pattern 115 at positions (e.g., such as P1, P2 and so on) may increase from the source region 113 toward the drain region 111. The thickness W1 of region I at the first position P1 may be larger than the thickness W2 of region I at the second position P2, for example.

The region II of the semiconductor pattern 115 may include a third position P3 that is spaced apart from the drain region 111 by a third distance D3. The distance D3 may be larger than the first distance D1 and the second distance D2. For example, the third distance D3 may be larger than the distance from the drain region 111 to the boundary between region I and region II. The thickness of the region II of the semiconductor pattern 115 at the third position P3 may be W3.

The semiconductor pattern 115 may be extended in a first direction X1. The gate structure 120 may be extended in a second direction X2 intersecting the first direction X1. The gate electrode 121 may intersect the semiconductor pattern 115, for example. More specifically, the gate electrode 121 may intersect region II of the semiconductor pattern 115, for example. The gate electrode 121 intersecting region II of the semiconductor pattern 115 may be a single gate electrode 121 to which the same voltage is applied.

The region III of the semiconductor pattern 115 may include a fourth position P4 that is spaced apart from the drain region 111 by a fourth distance D4. The fourth distance D4 may be larger than the first distance D1, the second distance D2 and the third distance D3. For example, the fourth distance D4 may be larger than the distance from the drain region 111 to the boundary between region II and region III. The thickness of the region III of the semiconductor pattern 115 at the fourth position P4 may be W4.

The region III of the semiconductor pattern 115 may include a fifth position P5 that is spaced apart from the drain region 111 by a fifth distance D5. The fifth distance D5 may be larger than the first distance D1, the second distance D2, the third distance D3 and the fourth distance D4. The thickness of the region III of the semiconductor pattern 115 at the fifth position P5 may be W5.

The thickness of region III of the semiconductor pattern 115 at certain positions (e.g., P4, P5, etc.) may be constant from the source region 113 toward the drain region 111. For example, the thickness W4 of region III of the semiconductor pattern 115 at the fourth position P4 may be substantially equal to the thickness W5 of region III of the semiconductor pattern 115 at the fifth position P5.

In other words, the distribution of the thickness of region III of the semiconductor pattern 115 at the fourth position P4 may be substantially equal to the distribution of the thickness of region III of the semiconductor pattern 115 at the fifth position P5.

In an exemplary embodiment, the thicknesses of region I of the semiconductor pattern 115 may be larger than the thickness of region II of the semiconductor pattern 115. The thickness of region I of the semiconductor pattern 115 may be the thickness W1 of region I at the first position P1, for example. In addition, the thickness of region II of the semiconductor pattern 115 may be the thickness W3 of region II at the third position P3, for example.

The thicknesses of region I of the semiconductor pattern 115 may be larger than the thickness of region III of the semiconductor pattern 115, for example. In this regard, the thickness of region I of the semiconductor pattern 115 may be the thickness W1 of region I at the first position P1, for example. In addition, the thickness of region III of the semiconductor pattern 115 may be the thickness W4 of region III at the fourth position P4, for example.

The thickness of region III of the semiconductor pattern 115 may be substantially equal to the thickness of region II of the semiconductor pattern 115. In other words, the distribution of thickness of region III of the semiconductor pattern 115 may be, for example, substantially equal to the distribution of thickness of region II of the semiconductor pattern 115.

In this regard, the thickness of region III of the semiconductor pattern 115 may be the thickness W4 of region III at the fourth position P4, for example. In addition, the thickness of region II of the semiconductor pattern 115 may be the thickness W3 of region II at the third position P3, for example.

The thicknesses W1 to W5 may be measured in the second direction X2, for example. The second direction X2 may refer to the direction in which the gate electrode 121 is extended, for example. The second direction X2 may intersect the direction in which the semiconductor pattern 115 is extended, for example.

In the foregoing descriptions, the thickness of each of portions of the semiconductor pattern 115 has been described as a thickness in the second direction X2 at a position spaced apart from the drain region 111 by a predetermined distance. However, this is merely illustrative. Alternatively, the thickness of each portion of the semiconductor pattern 115 may be an average of thicknesses at each portion of the semiconductor pattern 115. For example, the thickness of region I may be an average of thicknesses in the second direction X2 (e.g., W1 and W2) at positions (e.g., P1 and P2) spaced apart from the drain region 111 by predetermined distances.

The semiconductor device according to an exemplary embodiment can reduce self-heating or ionization by way of making the semiconductor pattern 115 working as a channel region thicker near the drain region 111 than near the source region 113. As a result, reliability of semiconductor devices can be enhanced.

In the semiconductor device according to an exemplary embodiment, the thickness of the portion of the semiconductor pattern 115 closer to the drain region 111 is larger than the thickness of the center portion of the semiconductor pattern 115, such that reliability of semiconductor devices can be enhanced.

Hereinafter, processing steps of a method for fabricating a semiconductor device according to an exemplary embodiment will be described. Initially, a fin-like pattern may be formed on a substrate. In an exemplary embodiment, after forming the fin-like pattern, a part of the fin-like pattern may be patterned so that a semiconductor pattern may be formed.

However, this is not limited thereto. For example, after forming the fin-like pattern, a field insulation film may be formed without patterning a part of the fin-like pattern. In this case, a portion of the fin-like pattern that protrudes from the upper surface of the field insulation film may be patterned.

Alternatively, a dummy gate electrode or the like may be formed on the fin-like pattern without patterning the portion of the fin-like pattern that protrudes from the upper surface of the field insulation film. In the case of a gate-last process, the dummy gate electrode may be removed after a source region and a drain region have been formed. At this time, the fin-like pattern may be patterned so that a semiconductor pattern may be formed.

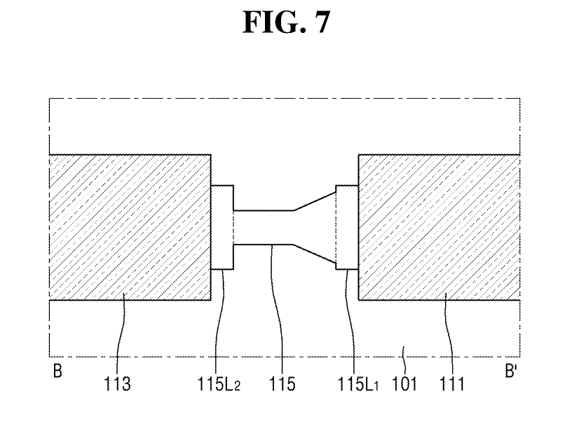

Hereinafter, a semiconductor device according to exemplary embodiments will be described with reference to FIGS. 1 and 7. For clarity of illustration, the redundant description will be omitted. In FIG. 7, the gate structure 120 and the like are not shown for clarity of illustration.

FIG. 7 is a cross-sectional view taken along line B-B′ of FIG. 1.

Referring to FIGS. 1 and 7, connection regions 115L₁ and 115L₂ may be further disposed between the semiconductor pattern 115 and drain region 111 and between the semiconductor pattern 115 and the source region 113, respectively. The connection regions 115L₁ and 115L₂ may be parts of the fin-like pattern 110.

For example, in a gate-last process or the like, the dummy gate electrode may be removed after the drain region 111 and the source region 113 have been formed. Dummy gate spacers, however, may remain. The dummy gate spacers may be formed on the connection regions 115L₂ and 115L₁. At the time of patterning the fin-like pattern exposed after the dummy gate electrode has been removed, the connection regions 115L₂ and 115L₁ may not be patterned due to the dummy gate spacers. At least one of the connection regions 115L₂ and 115L₁ may be removed during a subsequent process.

Hereinafter, a semiconductor device according to exemplary embodiments will be described with reference to FIGS. 1, 8 and 9. For clarity of illustration, the redundant description will be omitted.

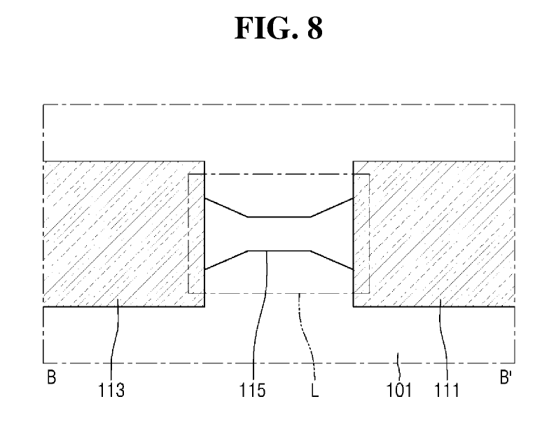

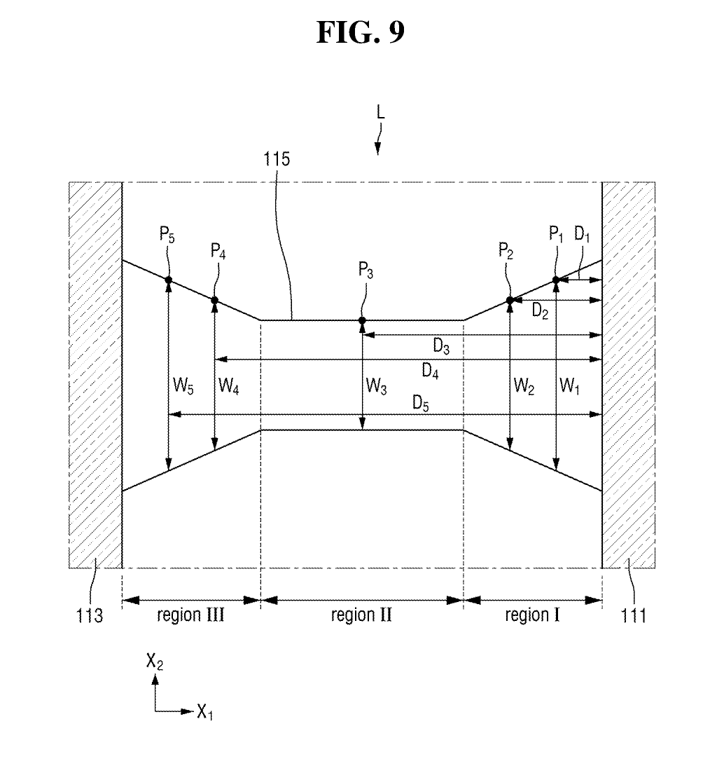

FIG. 8 is a cross-sectional view taken along line B-B′ of FIG. 1. FIG. 9 is an enlarged view of area L shown in FIG. 8. In FIGS. 8 and 9, the gate structure 120 and the like are not shown for clarity of illustration.

Referring to FIGS. 1, 8 and 9, the thicknesses of region III of the semiconductor pattern 115 at positions such as P4, P5 and so on may decrease toward the drain region 111 from the source region 113.

For example, the thickness W4 of region III of the semiconductor pattern 115 at the fourth position P4 may be smaller than the thickness W5 of region III of the semiconductor pattern 115 at the fifth position P5.

The thickness of region III of the semiconductor pattern 115 may be larger than the thickness of region II of the semiconductor pattern 115. In this regard, the thickness of region III of the semiconductor pattern 115 may be the thickness W4 of region III at the fourth position P4, for example. The thickness of region II of the semiconductor pattern 115 may be the thickness W3 of region II at the third position P3, for example.

The thickness of region III of the semiconductor pattern 115 may be substantially equal to the thickness of region I of the semiconductor pattern 115. In other words, the distribution of thickness of region III of the semiconductor pattern 115 may be, for example, substantially equal to the distribution of thickness of region I of the semiconductor pattern 115. However, the thickness of region III of the semiconductor pattern 115 may be smaller than the thickness of region I of the semiconductor pattern 115.

In this regard, the thickness of region I of the semiconductor pattern 115 may be the thickness W1 of region I at the first position P1, for example.

In the foregoing descriptions, the thickness of each of portions of the semiconductor pattern 115 has been described as a thickness in the second direction X2 at a position spaced apart from the drain region 111 by a predetermined distance. However, this is merely illustrative. The thickness of region III of the semiconductor pattern 115 may be, for example, an average of thicknesses of region III of the semiconductor pattern 115. For example, the thickness of region III may be an average of thicknesses in the second direction X2 (e.g., W4 and W5) at positions (e.g., P4 and P5) spaced apart from the drain region 111 by predetermined distances.

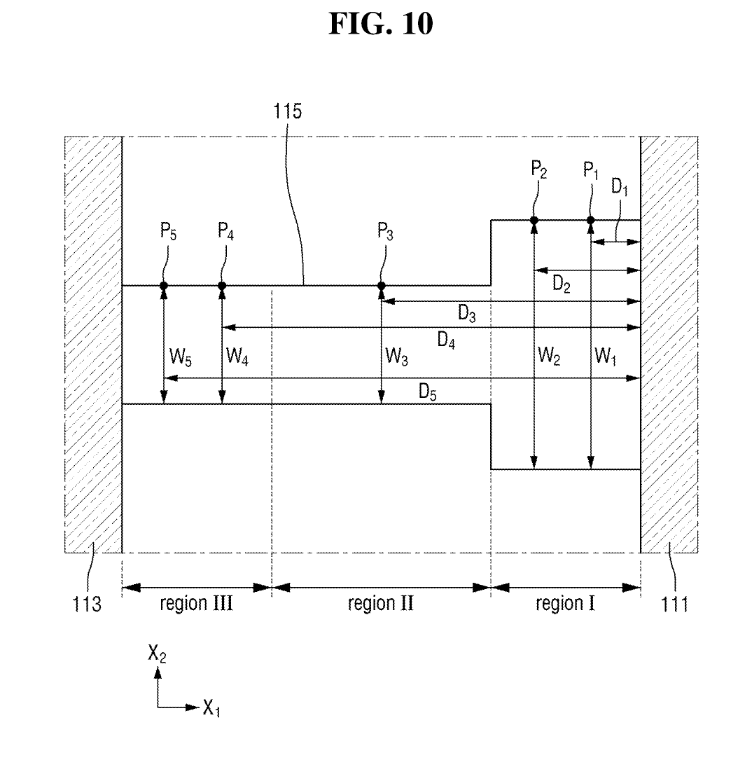

Hereinafter, a semiconductor device according to an exemplary embodiment will be described with reference to FIGS. 1 and 10. For clarity of illustration, the redundant description will be omitted.

FIG. 10 is a view for illustrating a semiconductor device according to an exemplary embodiment. Specifically, FIG. 10 is an enlarged, cross-sectional view of a portion of the semiconductor pattern 115 taken along line B-B′ of FIG. 1. In FIG. 10, the gate structure 120 and the like are not shown for clarity of illustration.

Referring to FIGS. 1 and 10, the thicknesses W1 of region I of the semiconductor pattern 115 at the first position P1 may be substantially equal to the thickness W2 at the second position P2.

For example, the thickness of region I of the semiconductor pattern 115 may be constant from the source region 113 toward the drain region 111. In an exemplary embodiment, region I of the semiconductor pattern 115 may have a rectangular shape.

Although the side wall of the region II of the semiconductor pattern 115 comes in contact with the side wall of region I of the semiconductor pattern 115 at right angle in FIG. 10, this is merely illustrative. For example, it is to be understood that the side wall of the region II of the semiconductor pattern 115 may come in contact with the side wall of region I of the semiconductor pattern 115 at any angle.

The thickness of region III of the semiconductor pattern 115 may be generally constant from the source region 113 toward the drain region 111. For example, the thickness W4 of region III of the semiconductor pattern 115 at the fourth position P4 may be substantially equal to the thickness W5 at the fifth position P5.

The thickness of region I of the semiconductor pattern 115 may be larger than the thickness of each of region II and region III. The thickness of region II of the semiconductor pattern 115 may be substantially equal to the thickness of region III.

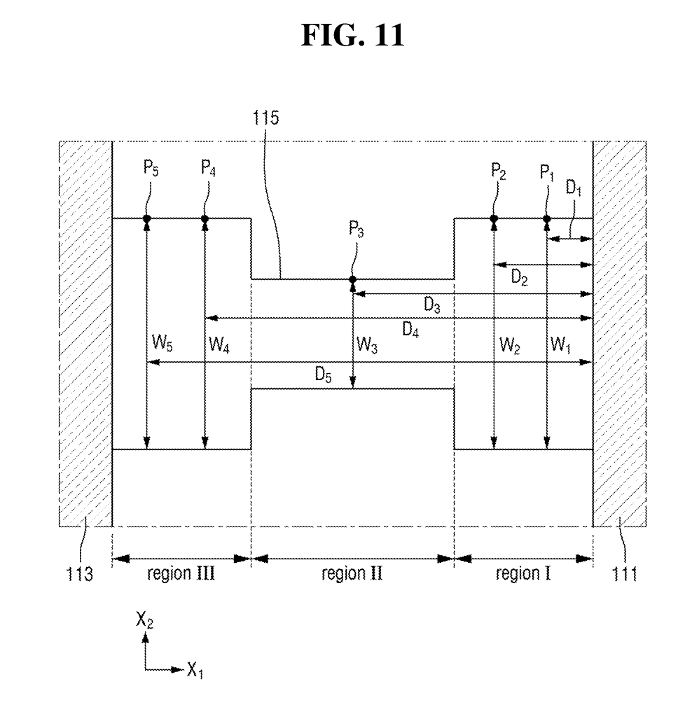

Hereinafter, a semiconductor device according to an exemplary embodiment will be described with reference to FIGS. 1 and 11. For clarity of illustration, the redundant description will be omitted.

FIG. 11 is a view for illustrating a semiconductor device according to some exemplary embodiment of the present disclosure. Specifically, FIG. 11 is an enlarged, cross-sectional view of a portion of the semiconductor pattern 115 taken along line B-B′ of FIG. 1. In FIG. 11, the gate structure 120 and the like are not shown for clarity of illustration.

Referring to FIGS. 1 and 11, the thickness of region III of the semiconductor pattern 115 may be generally constant from the drain region 111 toward the source region 113.

For example, the thickness of region I of the semiconductor pattern 115 at the first position P1 may be substantially equal to the thickness of region III of the semiconductor pattern 115 at the fourth position P4. However, the thickness of region III of the semiconductor pattern 115 may be smaller than the thickness of region I of the semiconductor pattern 115, for example.

In an exemplary embodiment, region I and region III of the semiconductor pattern 115 may have rectangular shapes.

Although the side wall of the region II of the semiconductor pattern 115 comes in contact with the side wall of region III of the semiconductor pattern 115 at right angle in FIG. 11, this is merely illustrative. For example, it is to be understood that the side wall of the region II of the semiconductor pattern 115 may come in contact with the side wall of region III of the semiconductor pattern 115 at any angle.

The thickness of region II of the semiconductor pattern 115 may be smaller than the thickness of each of region I and region III.

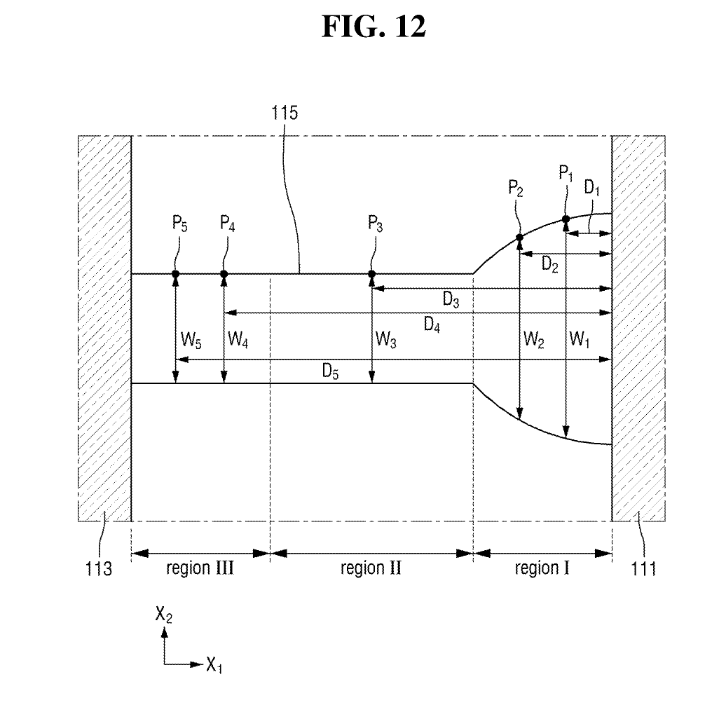

Hereinafter, a semiconductor device according to an exemplary embodiment will be described with reference to FIGS. 1 and 12. For clarity of illustration, the redundant description will be omitted.

FIG. 12 is a view for illustrating a semiconductor device according to an exemplary embodiment. Specifically, FIG. 12 is an enlarged, cross-sectional view of a portion of the semiconductor pattern 115 taken along line B-B′ of FIG. 1. In FIG. 12, the gate structure 120 and the like are not shown for clarity of illustration.

Referring to FIGS. 1 and 12, the side wall of region I of the semiconductor pattern 115 may have a rounded shape.

For example, one side wall of region I may come in contact with region II of the semiconductor pattern 115. The other side wall of region I of the semiconductor pattern 115 may be connected to the drain region 111, for example.

The thickness of region I of the semiconductor pattern 115 may increase from the source region 113 toward the drain region 111. For example, the thickness W1 of region I of the semiconductor pattern 115 at the first position P1 may be larger than the thickness W2 at the second position P2.

The thickness of region I of the semiconductor pattern 115 may be larger than the thickness of each of region II and region III. The thickness of region II of the semiconductor pattern 115 may be substantially equal to the thickness of region III.

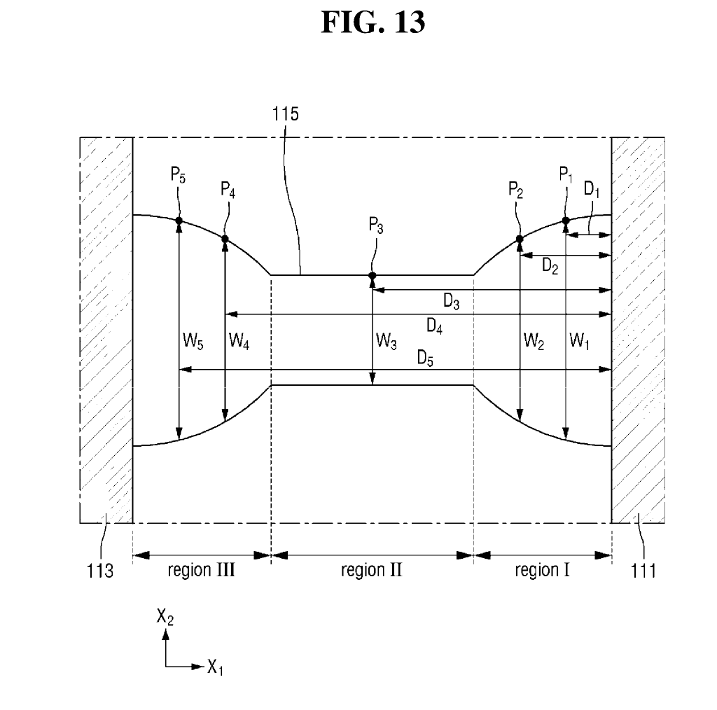

Hereinafter, a semiconductor device according to an exemplary embodiment will be described with reference to FIGS. 1 and 13. For clarity of illustration, the redundant description will be omitted.

FIG. 13 is a view for illustrating a semiconductor device according to an exemplary embodiment. Specifically, FIG. 13 is an enlarged, cross-sectional view of a portion of the semiconductor pattern 115 taken along line B-B′ of FIG. 1. In FIG. 13, the gate structure 120 and the like are not shown for clarity of illustration.

Referring to FIGS. 1 and 13, the side wall of region III of the semiconductor pattern 115 may have a rounded shape.

For example, one side wall of region III may come in contact with region II of the semiconductor pattern 115. The other side wall of region III of the semiconductor pattern 115 may be connected to the source region 113, for example.

The thickness of region III of the semiconductor pattern 115 may increase from the drain region 111 toward the source region 113. For example, the thickness W4 of region III of the semiconductor pattern 115 at the fourth position P4 may be smaller than the thickness W5 at the fifth position P5.

The thickness of region I of the semiconductor pattern 115 may be substantially equal to the thickness of region III. However, the thickness of region III of the semiconductor pattern 115 may be smaller than the thickness of region I of the semiconductor pattern 115, for example.

The thickness of region II of the semiconductor pattern 115 may be smaller than the thickness of each of region I and region III.

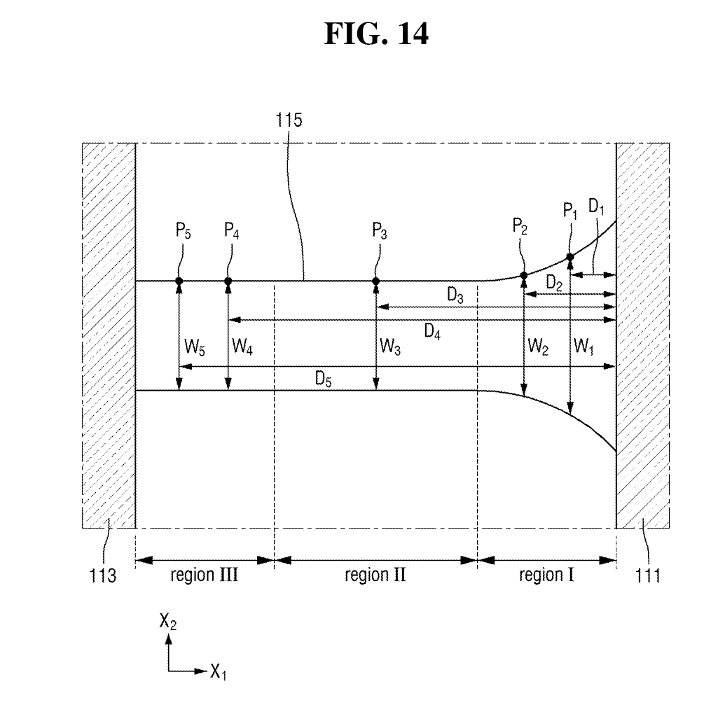

Hereinafter, a semiconductor device according to an exemplary embodiment will be described with reference to FIGS. 1 and 14. For clarity of illustration, the redundant description will be omitted.

FIG. 14 is a view for illustrating a semiconductor device according to an exemplary embodiment. Specifically, FIG. 14 is an enlarged, cross-sectional view of a portion of the semiconductor pattern 115 taken along line B-B′ of FIG. 1. In FIG. 14, the gate structure 120 and the like are not shown for clarity of illustration.

Referring to FIGS. 1 and 14, the side wall of region I of the semiconductor pattern 115 may have a tapered shape.

For example, one side wall of region I of the semiconductor pattern 115 may come in contact with region II of the semiconductor pattern 115. The other side wall of region I of the semiconductor pattern 115 may be connected to the drain region 111, for example.

The thickness of region I of the semiconductor pattern 115 may increase from the source region 113 toward the drain region 111. For example, the thickness W1 of region I of the semiconductor pattern 115 at the first position P1 may be larger than the thickness W2 at the second position P2.

The thickness of region I of the semiconductor pattern 115 may be larger than the thickness of each of region II and region III. The thickness of region II of the semiconductor pattern 115 may be substantially equal to the thickness of region III.

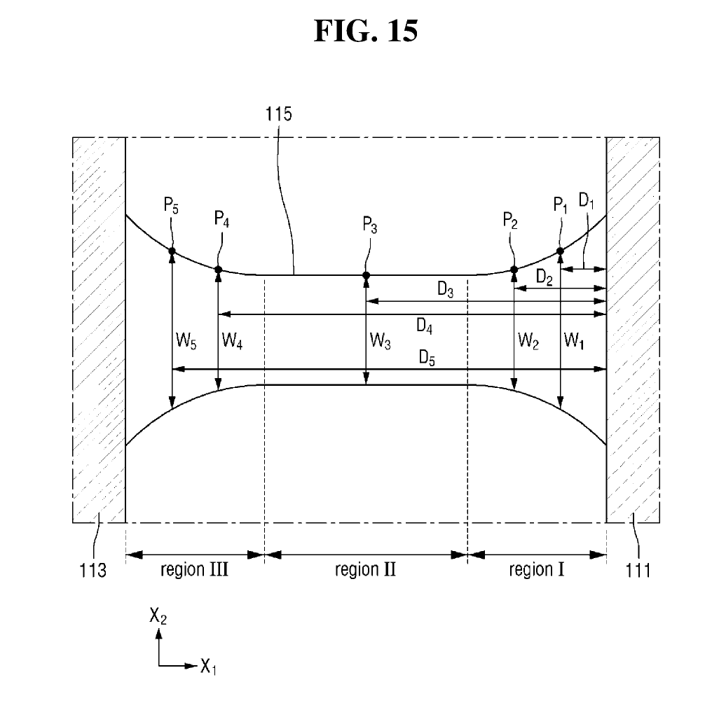

Hereinafter, a semiconductor device according to an exemplary embodiment will be described with reference to FIGS. 1 and 15. For clarity of illustration, the redundant description will be omitted.

FIG. 15 is a view for illustrating a semiconductor device according to an exemplary embodiment. Specifically, FIG. 15 is an enlarged, cross-sectional view of a portion of the semiconductor pattern 115 taken along line B-B′ of FIG. 1. In FIG. 15, the gate structure 120 and the like are not shown for clarity of illustration.

Referring to FIGS. 1 and 15, the side wall of region III of the semiconductor pattern 115 may have a tapered shape.

For example, one side wall of region III may come in contact with region II of the semiconductor pattern 115. The other side wall of region III of the semiconductor pattern 115 may be connected to the source region 113, for example.

The thickness of region III of the semiconductor pattern 115 may increase from the drain region 111 toward the source region 113. For example, the thickness W4 of region III of the semiconductor pattern 115 at the fourth position P4 may be smaller than the thickness W5 at the fifth position P5.

The thickness of region I of the semiconductor pattern 115 may be substantially equal to the thickness of region III. However, the thickness of region III of the semiconductor pattern 115 may be smaller than the thickness of region I of the semiconductor pattern 115, for example.

The thickness of region II of the semiconductor pattern 115 may be smaller than the thickness of each of region I and region III.

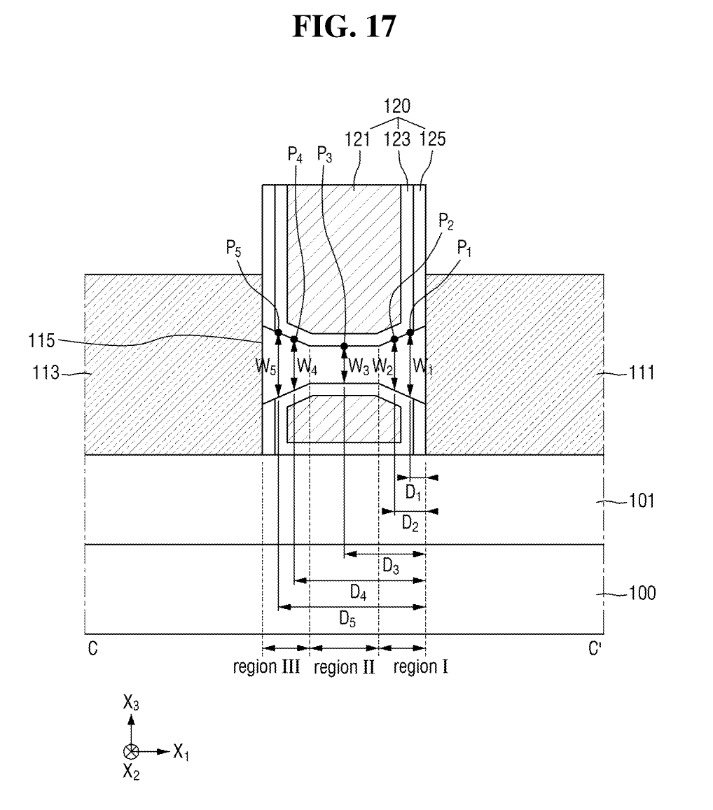

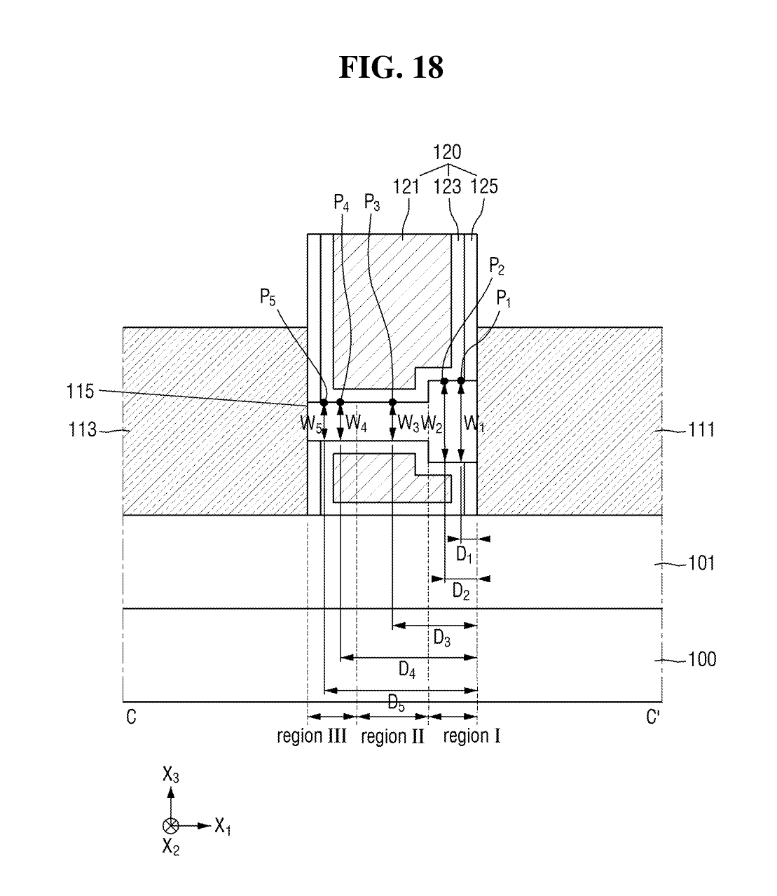

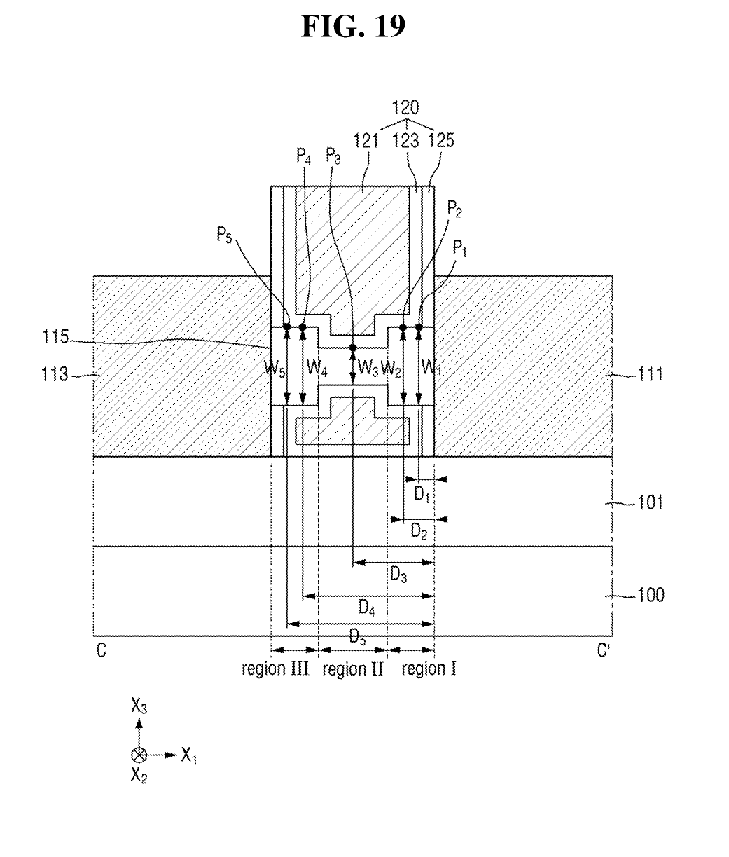

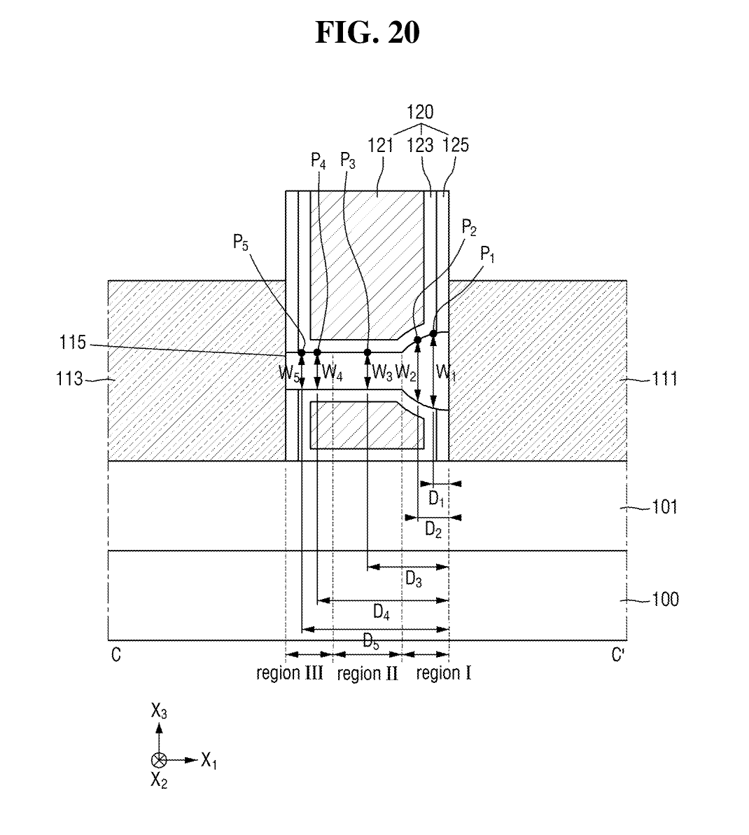

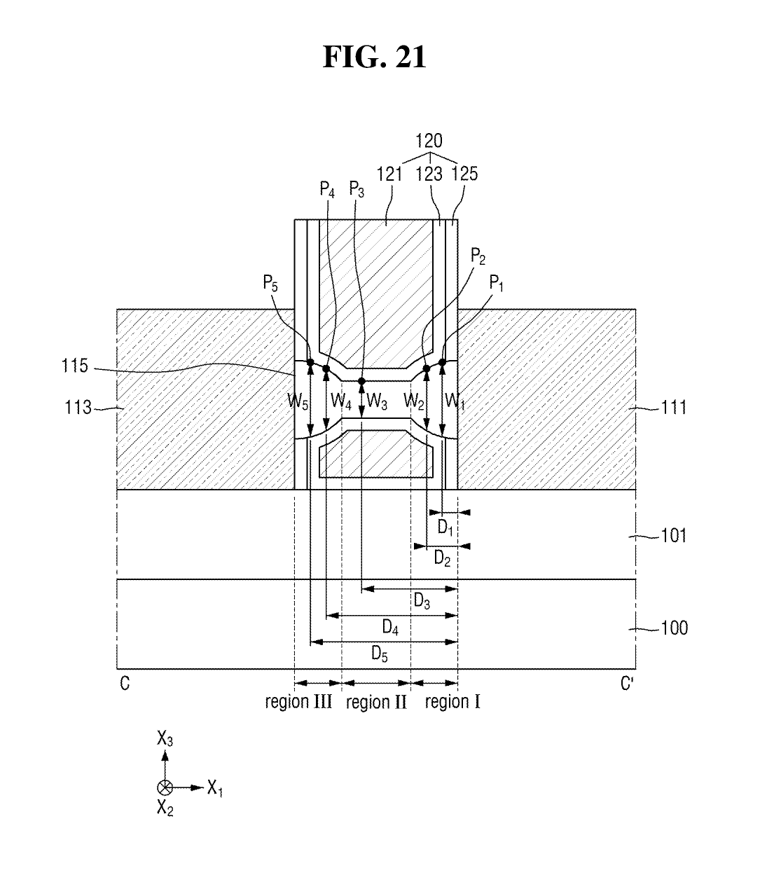

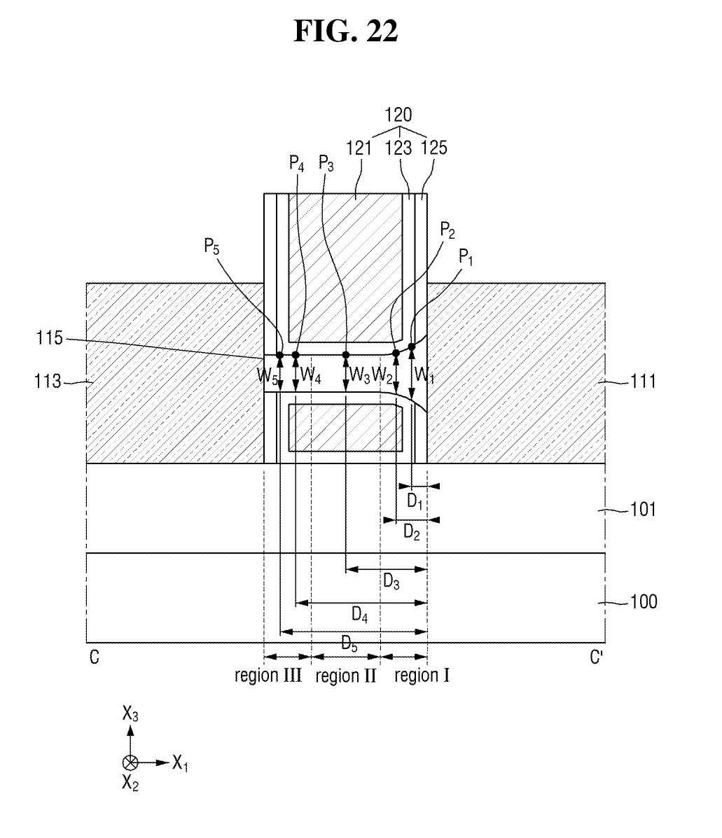

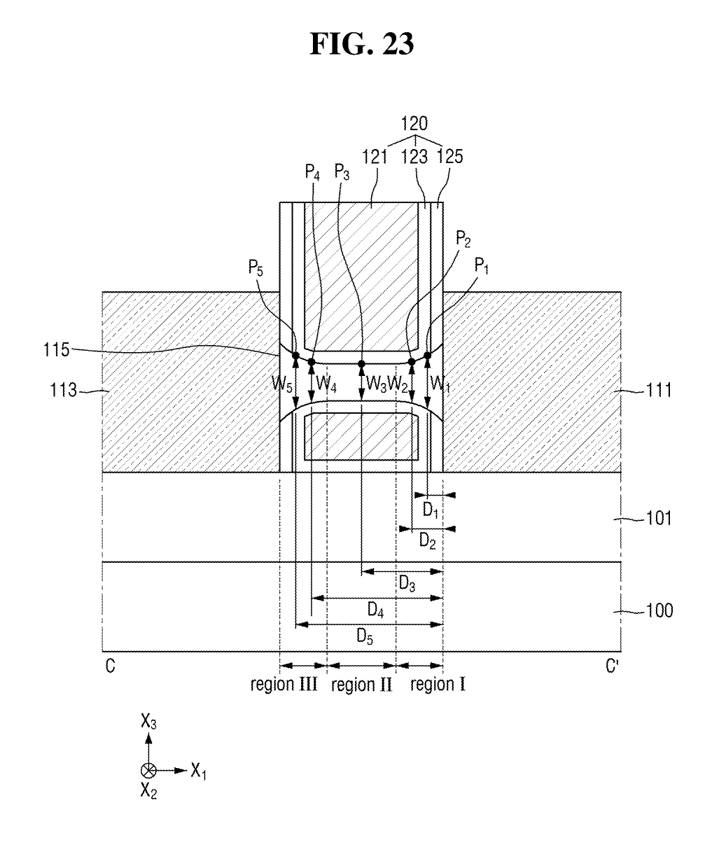

Hereinafter, a semiconductor device according to exemplary embodiments will be described with reference to FIGS. 1 and 16 to 23. For clarity of illustration, the redundant description will be omitted.

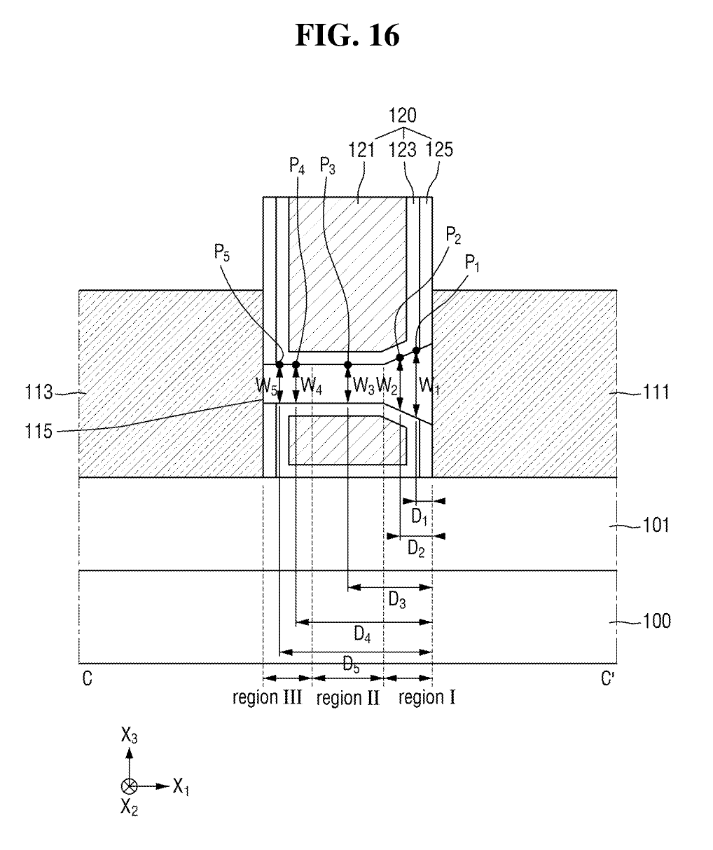

FIGS. 16 to 23 are cross-sectional views taken along line C-C′ of FIG. 1.

Referring to FIGS. 1 and 16 to 23, a semiconductor pattern 115 may have a wire shape.

The semiconductor pattern 115 may be formed above a substrate 100 with spacing therebetween. The semiconductor pattern 115 may penetrate a gate structure 120. A part of a gate electrode 121 may be interposed between the semiconductor pattern 115 and the substrate 100. In other words, the gate electrode 121 may surround the semiconductor pattern 115.

A gate insulation film 123 may be formed between the gate electrode 121 and a gate spacer 125 and between the gate electrode 121 and the substrate 100. In addition, the gate insulation film 123 may surround the semiconductor pattern 115.

Thickness of each of portions of the semiconductor pattern 115 may be measured in a third direction X3 which may refer to the direction that penetrates the substrate 100. For example, the third direction X3 may be perpendicular to the substrate 100. In exemplary embodiments, the third direction X3 may intersect a first direction X1 in which the semiconductor pattern 115 is extended and a second direction X2 in which the gate structure 120 is extended.

However, this is not limited thereto. For example, the thickness of each portion of the semiconductor pattern 115 may be the diameter of the semiconductor pattern 115.

For example, the thickness of region I of the semiconductor pattern 115 may be the diameter W1 of region I at a first position P1 spaced apart from the drain region 111 by a first distance D1. For example, the thickness of region II of the semiconductor pattern 115 may be the diameter W3 of region II at a third position P3 spaced apart from the drain region 111 by a third distance D3. For example, the thickness of region III of the semiconductor pattern 115 may be the diameter W4 of region III at a fourth position P4 spaced apart from the drain region 111 by a fourth distance D4.

Alternatively, the thickness of each portion of the semiconductor pattern 115 may be an average of diameters at positions spaced apart from the drain region 111 by predetermined distances.

For example, the thickness of region I of the semiconductor pattern 115 may be an average of diameters (e.g., W1, W2, etc.) at positions (e.g., P1, P2, etc.) spaced apart from the drain region 111 by predetermined distances.

For example, the thickness of region III of the semiconductor pattern 115 may be an average of diameters (e.g., W4, W5, etc.) at positions (e.g., P4, P5, etc.) spaced apart from the drain region 111 by predetermined distances.

Referring to FIGS. 16 to 23, the thickness of region I of the semiconductor pattern 115 may be substantially equal to or larger than the thickness of region III. The thickness of region I of the semiconductor pattern 115 may be larger than the thickness of region II. The thickness of region III of the semiconductor pattern 115 may be substantially equal to or larger than the thickness of region II.

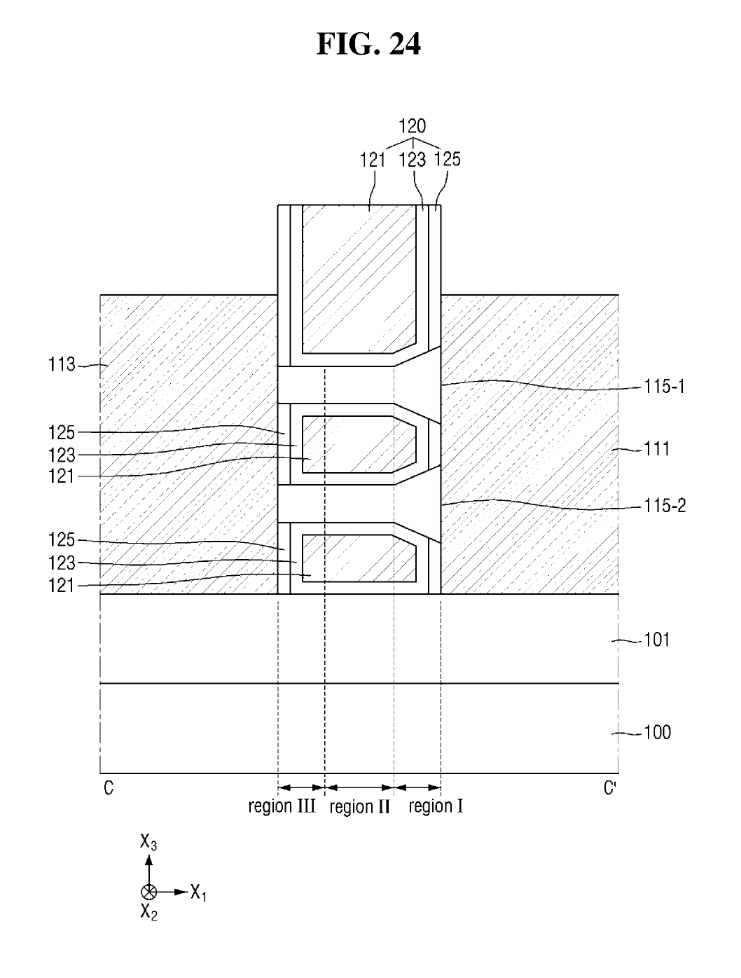

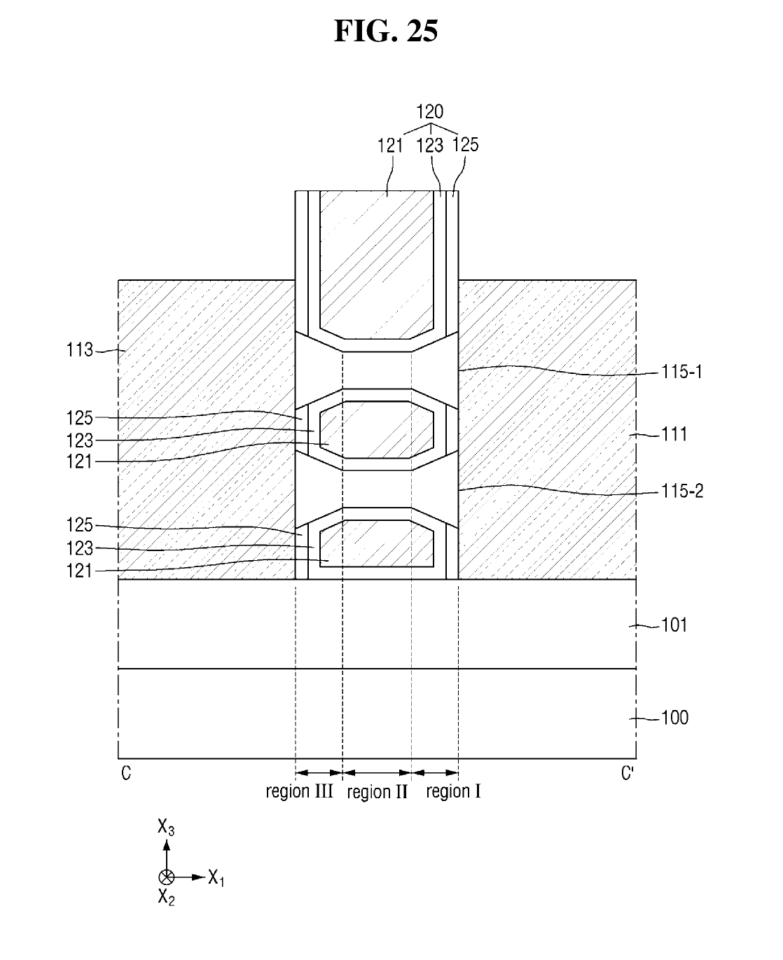

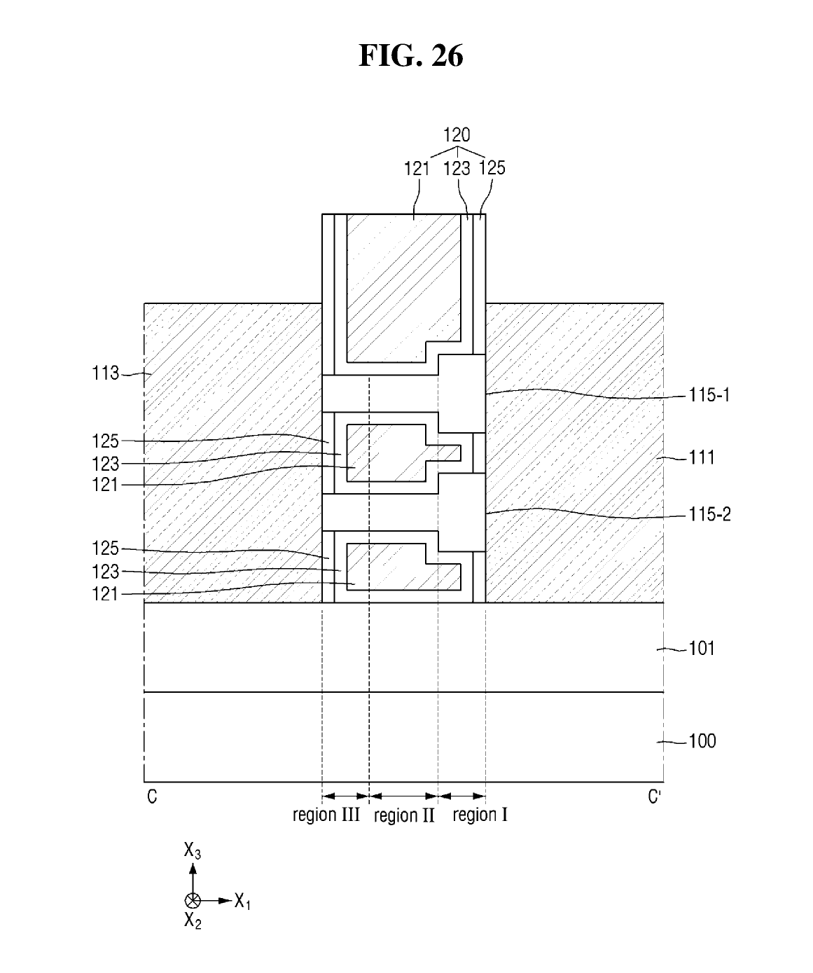

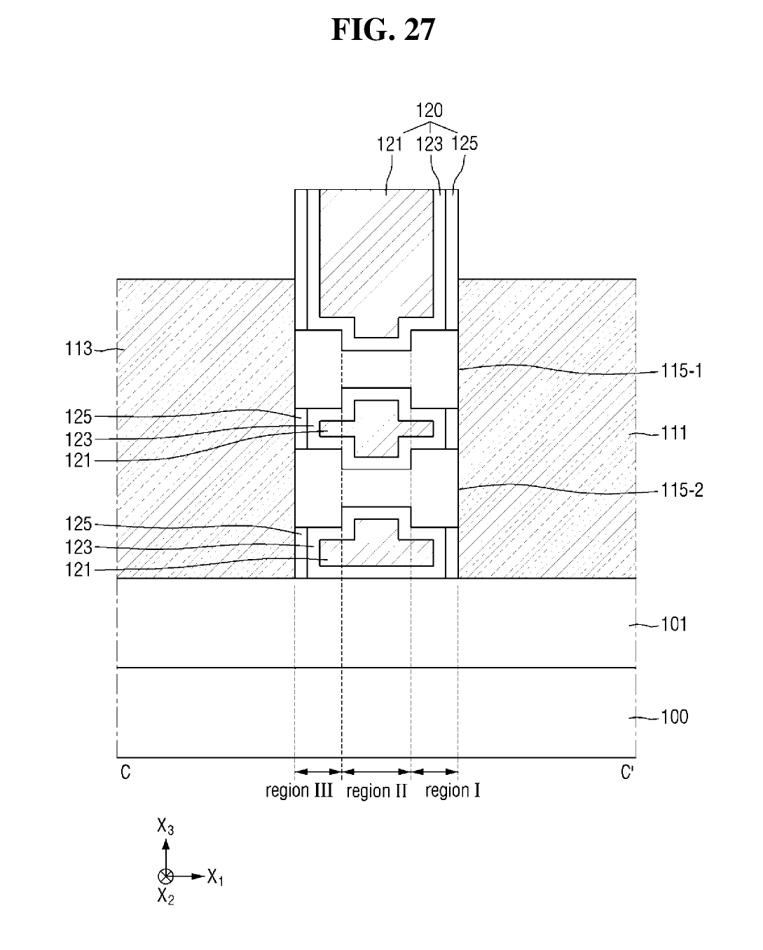

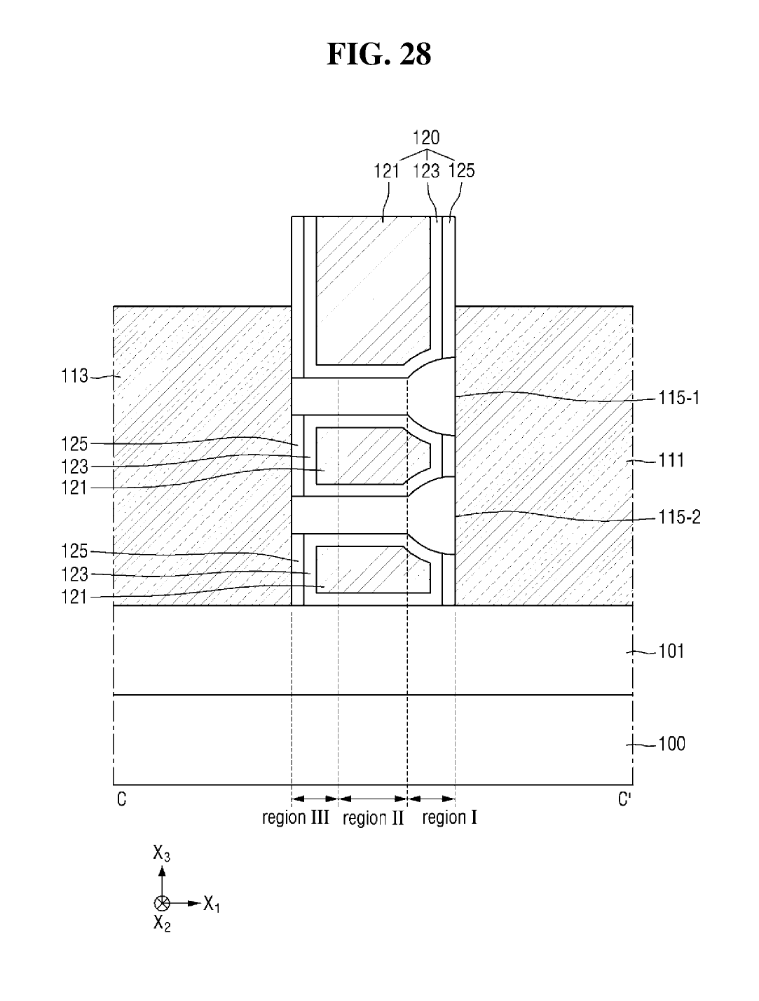

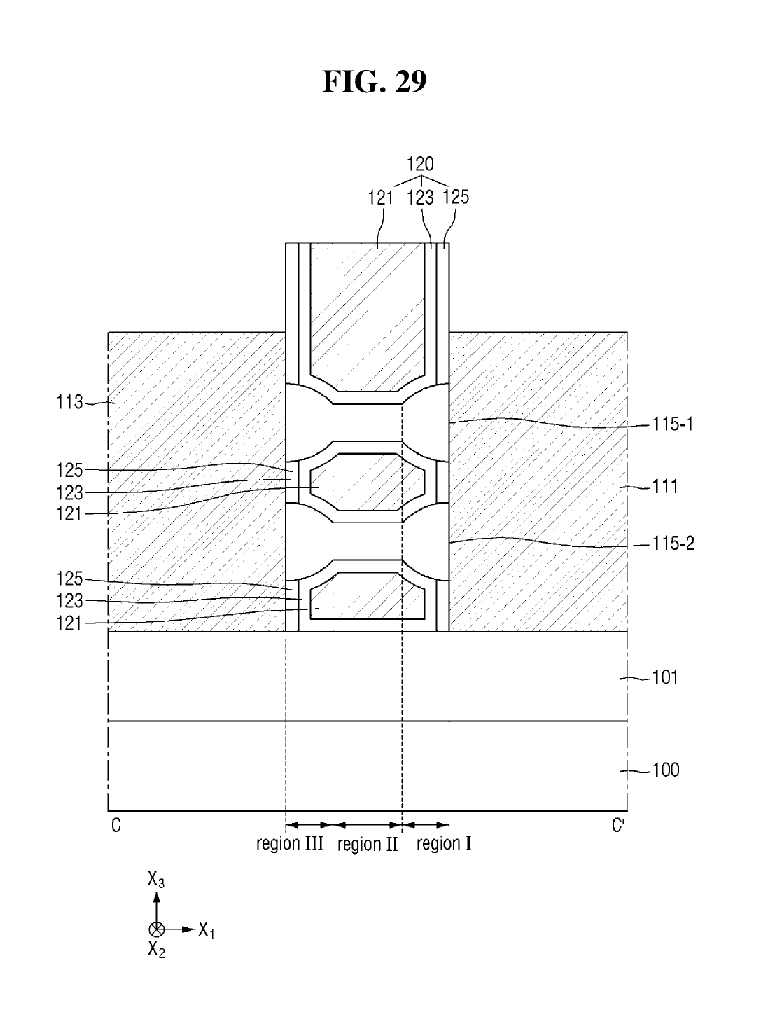

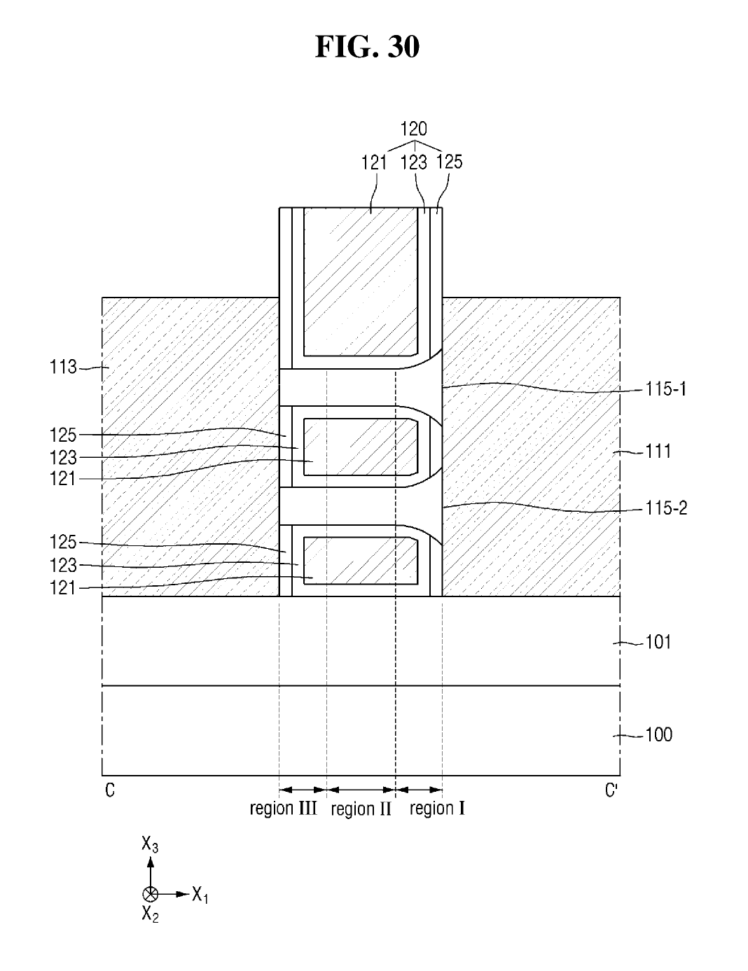

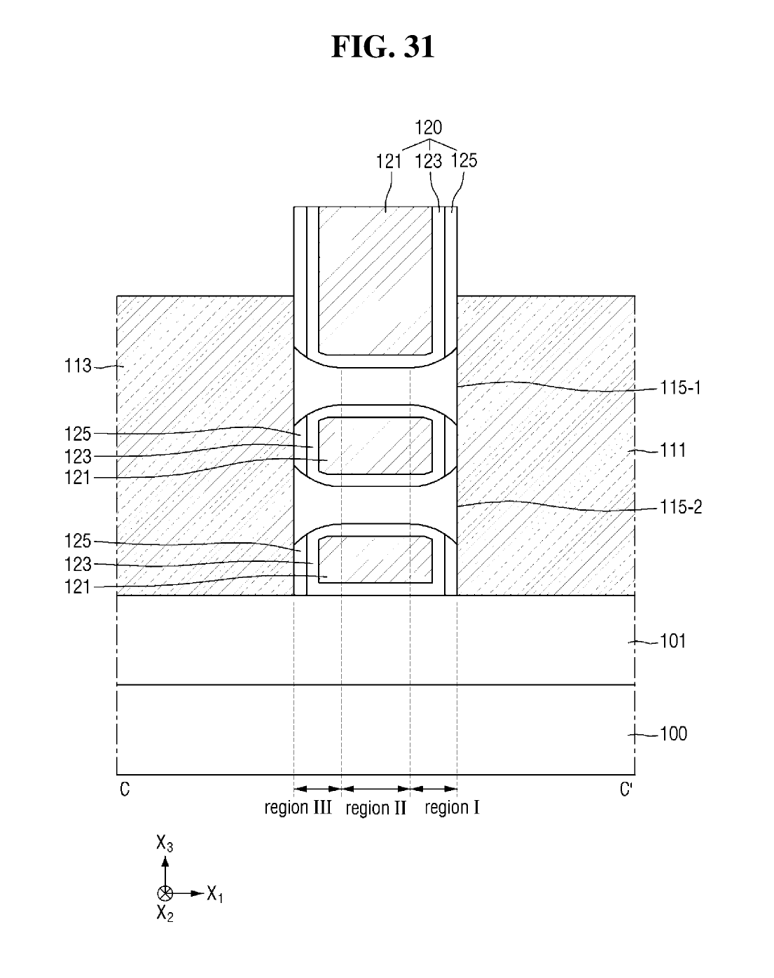

Hereinafter, a semiconductor device according to exemplary embodiments will be described with reference to FIGS. 24 to 31. For clarity of illustration, the redundant description will be omitted.

Referring to FIGS. 24 to 31, the semiconductor pattern 115 may include a first semiconductor pattern 115-1 and a second semiconductor pattern 115-2.

Each of the first and second semiconductor patterns 115-1 and 115-2 may be formed above the substrate 100 with spacing therebetween. The first and second semiconductor patterns 115-1 and 115-2 may be spaced apart from each other. The first semiconductor pattern 115-1 may be more distant from the substrate 100 than the second semiconductor pattern 115-2 is. The first and second semiconductor patterns 115-1 and 115-2 may have a wire shape, for example.

Each of the first and second semiconductor patterns 115-1 and 115-2 may include region I, region II and region III. The thicknesses of regions I, II and III of the first and second semiconductor patterns 115-1 and 115-2 are identical to those of the semiconductor pattern 115 described above; and, therefore, the redundant description will be omitted.

The first and second semiconductor patterns 115-1 and 115-2 may penetrate a gate structure 120. A part of a gate electrode 121 may be interposed between the first and second semiconductor patterns 115-1 and 115-2. In addition, another part of the gate electrode 121 may be interposed between the second semiconductor pattern 115-2 and the substrate 100. In other words, the gate electrode 121 may surround the first and second semiconductor patterns 115-1 and 115-2.

A gate insulation film 123 may surround the first and second semiconductor patterns 115-1 and 115-2.

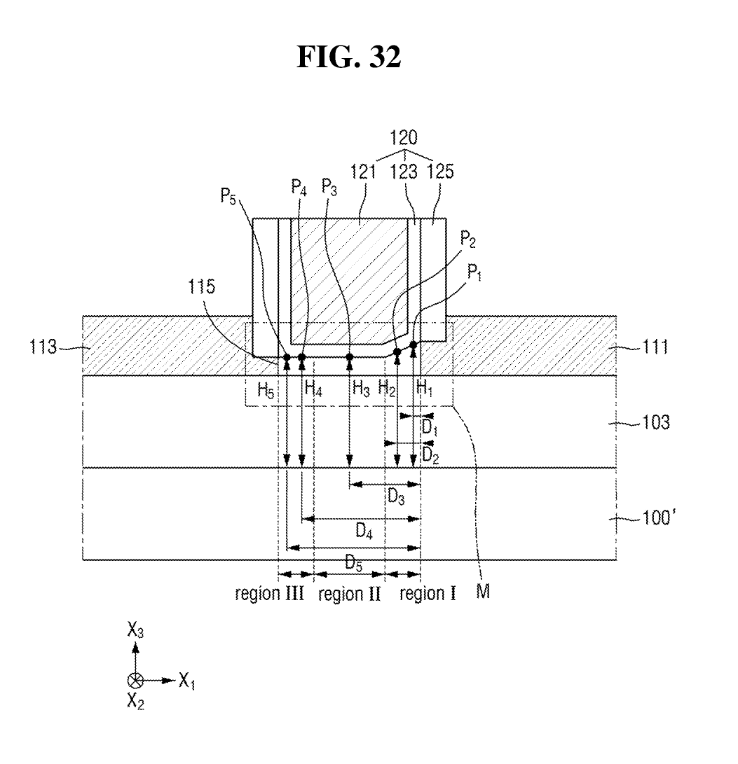

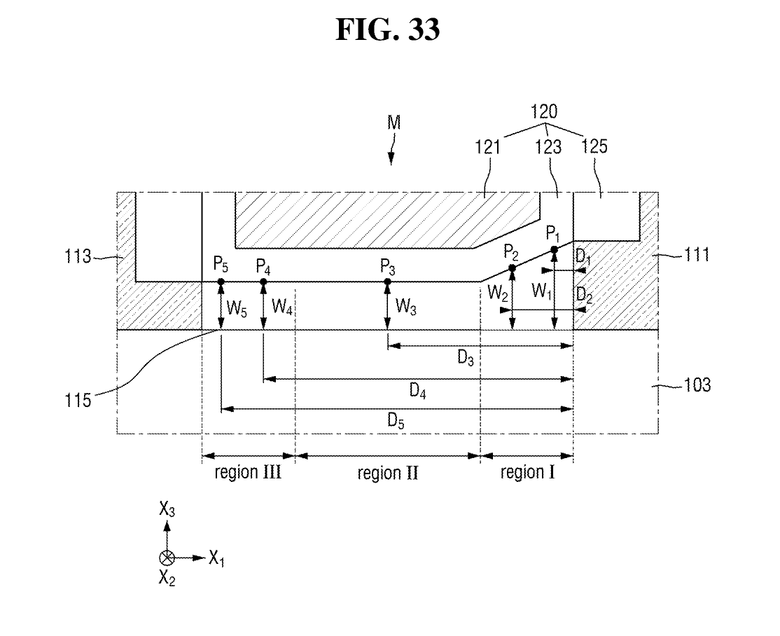

Hereinafter, a semiconductor device according to an exemplary embodiment will be described with reference to FIGS. 32 and 33. For clarity of illustration, the redundant description will be omitted.

FIG. 32 is a cross-sectional view of a semiconductor device according to an exemplary embodiment. FIG. 33 is an enlarged view of area M shown in FIG. 32.

Referring to FIGS. 32 and 33, the substrate 100 may include a base substrate 100′ and a buried oxide film 103. The buried oxide film 103 may be formed on the base substrate 100′.

The semiconductor pattern 115 may be formed on the buried oxide film 103. A drain region 111 and a sour region 113 may be formed on the buried oxide film 103.

The drain region 111, the source region 113 and the semiconductor pattern 115 may be extended in the same direction as the direction X2 in which the gate structure 120 is extended.

Thickness of each of portions of the semiconductor pattern 115 is measured in the third direction X3. For example, the third direction X3 may be perpendicular to the substrate 100. In exemplary embodiments, the third direction X3 may intersect the direction X2 in which the drain region 111, the source region 113 and the semiconductor pattern 115 are extended.

The thickness of region I of the semiconductor pattern 115 may be substantially equal to the thickness of region III. The thickness of region I of the semiconductor pattern 115 may be larger than the thickness of region II. The thickness of region III of the semiconductor pattern 115 may be substantially equal to the thickness of region II.

The symbol H1 may refer to the height of region I of the semiconductor pattern 115 at the first position P1 from the base substrate 100′ to the upper surface. The symbol H2 may refer to the height of region I of the semiconductor pattern 115 at the second position P2 from the base substrate 100′ to the upper surface.

At positions (e.g., P1, P2, etc.) of region I of the semiconductor pattern 115, the height of region I from the base substrate 100′ may increase from the source region 113 toward the drain region 111. For example, the height H1 may be larger than the height H2.

The symbol H3 may refer to the height of region II of the semiconductor pattern 115 at the third position P3 from the base substrate 100′ to the upper surface.

The symbol H4 may refer to the height of region III of the semiconductor pattern 115 at the fourth position P4 from the base substrate 100′ to the upper surface. The symbol H5 may refer to the height of region III of the semiconductor pattern 115 at the fifth position P5 from the base substrate 100′ to the upper surface.

At positions (e.g., P4, P5, etc.) of region III of the semiconductor pattern 115, the height of region III from the base substrate 100′ may be substantially constant from the source region 113 toward the drain region 111. For example, the height H4 may be substantially equal to the height H5.

In exemplary embodiments, the height H4 may be, but is not limited thereto, substantially equal to the height H3. For example, the height H4 may be larger than the height H3.

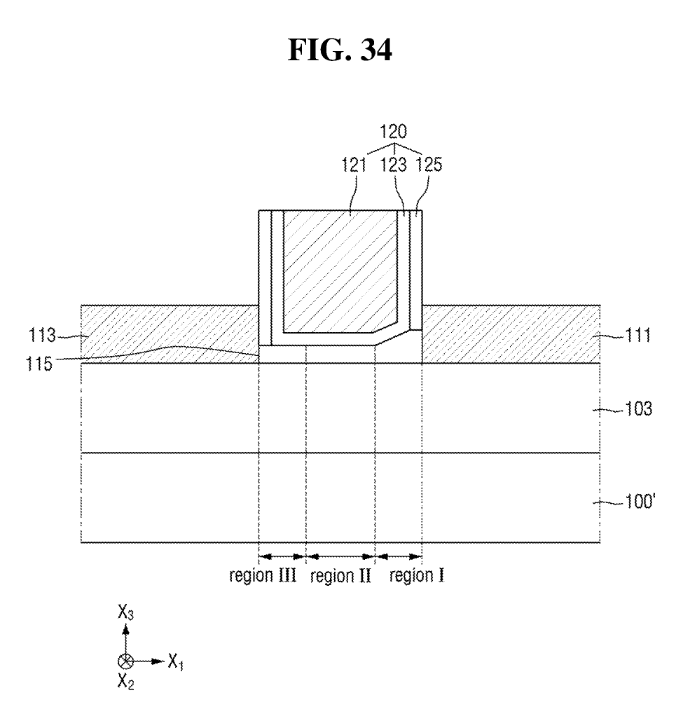

Hereinafter, a semiconductor device according to an exemplary embodiment will be described with reference to FIG. 34. For clarity of illustration, the redundant description will be omitted.

FIG. 34 is a cross-sectional view of a semiconductor device according to an exemplary embodiment.

Referring to FIG. 34, unlike FIG. 32, there is no area in which a gate spacer 125 vertically overlaps the drain region 111 or the source region 113. This may be the case in which the gate spacer 125 is formed after the semiconductor pattern 115 has been formed. On the other hand, in FIG. 32, the semiconductor pattern 115 is patterned after a dummy gate electrode has been removed, as in a gate-last process, for example. The following description will be made with reference to the example shown in FIG. 32

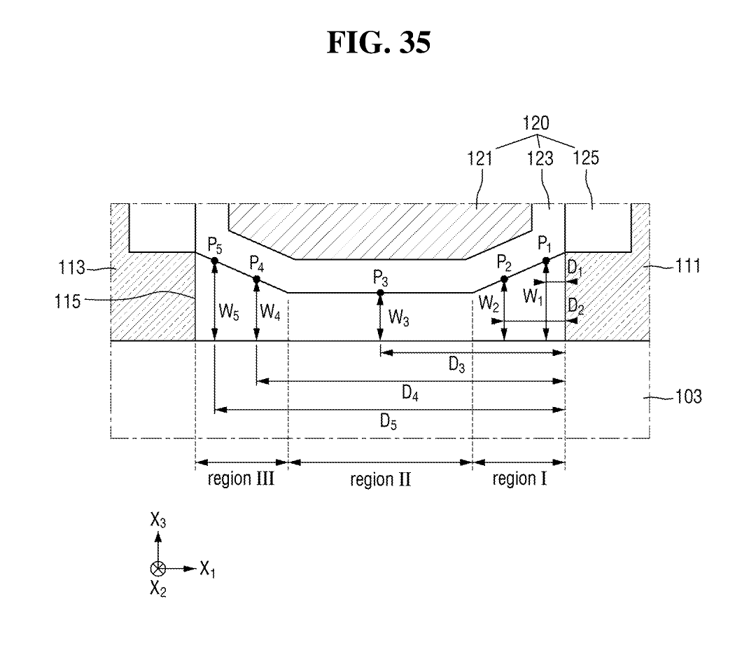

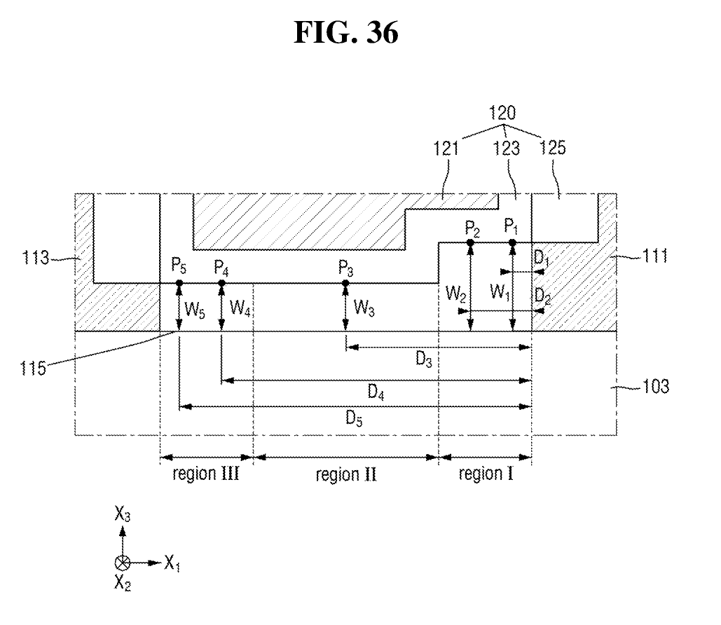

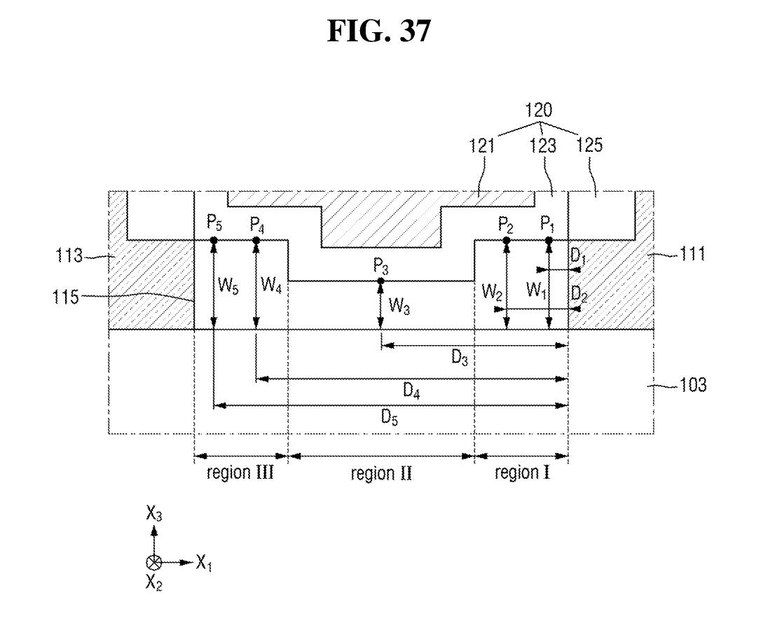

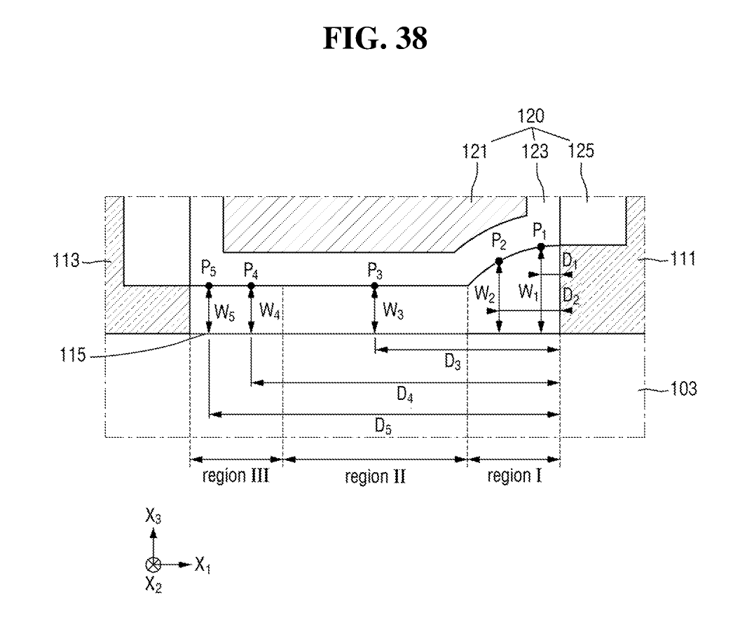

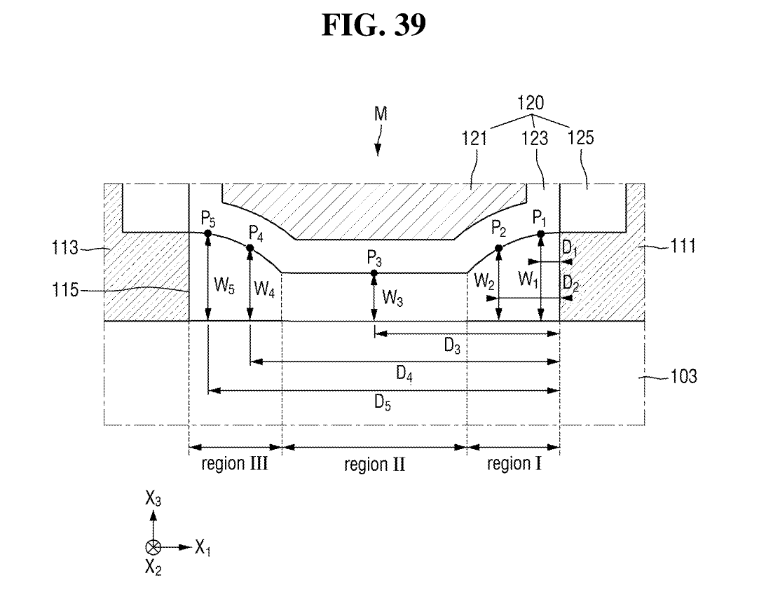

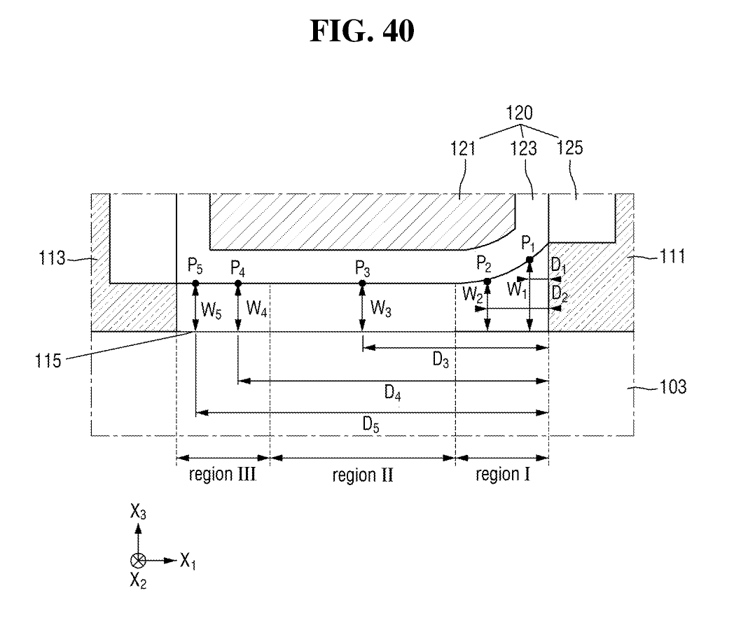

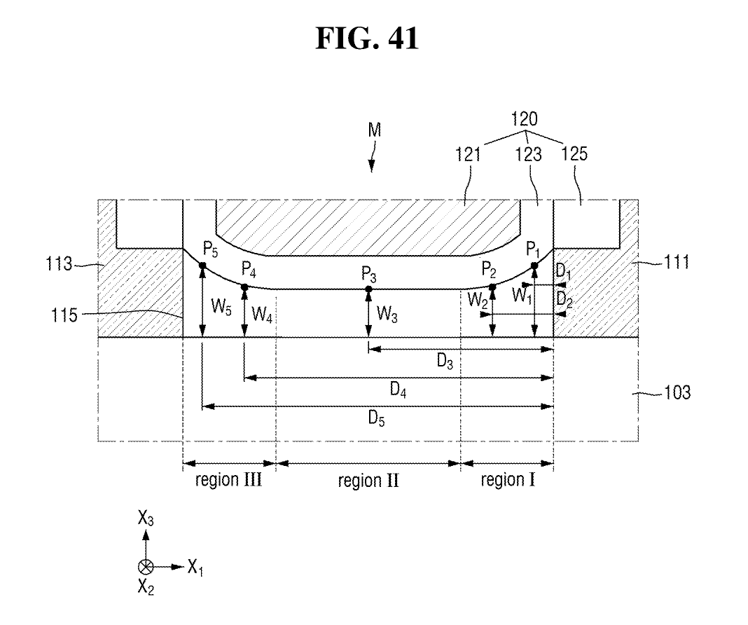

Hereinafter, a semiconductor device according to exemplary embodiments of will be described with reference to FIGS. 35 to 41. For clarity of illustration, the redundant description will be omitted.

FIGS. 35 to 41 are cross-sectional views for illustrating a semiconductor device according to exemplary embodiments. Specifically, FIGS. 35 to 41 are enlarged views of the semiconductor pattern 115 of the semiconductor device shown in FIG. 32.

Referring to FIGS. 35 to 41, at positions (e.g., P4, P5, etc.) in region III of the semiconductor pattern 115, the height of region III from the base substrate 100′ may be substantially constant or decrease from the source region 113 toward the drain region 111. For example, height H5 may be equal to or larger than the height H4. The symbol H5 may refer to the height from the base substrate 100′ to the upper surface of region III at the fifth position P5.

The thickness of region I of the semiconductor pattern 115 may be substantially equal to or larger than the thickness of region III. The thickness of region I of the semiconductor pattern 115 may be larger than the thickness of region II. The thickness of region III of the semiconductor pattern 115 may be substantially equal to or larger than the thickness of region II.

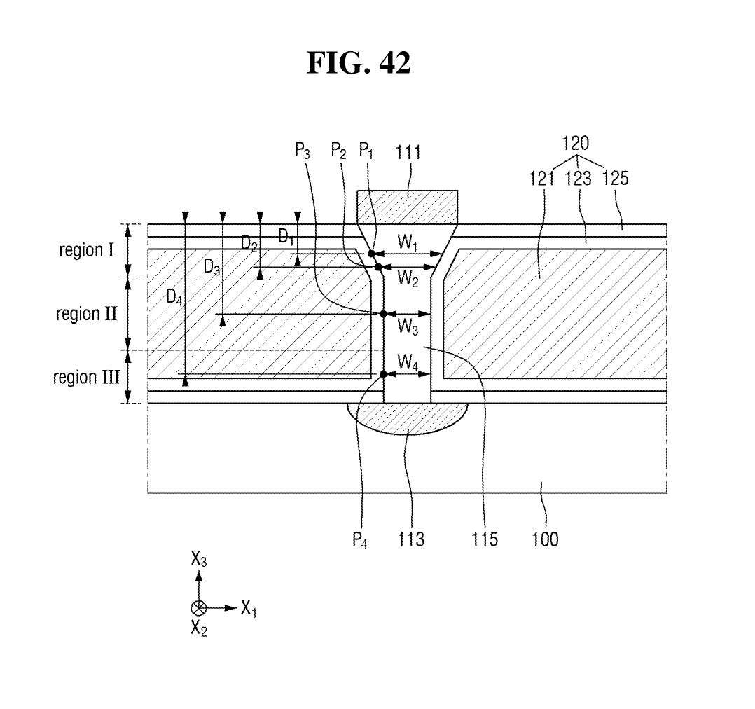

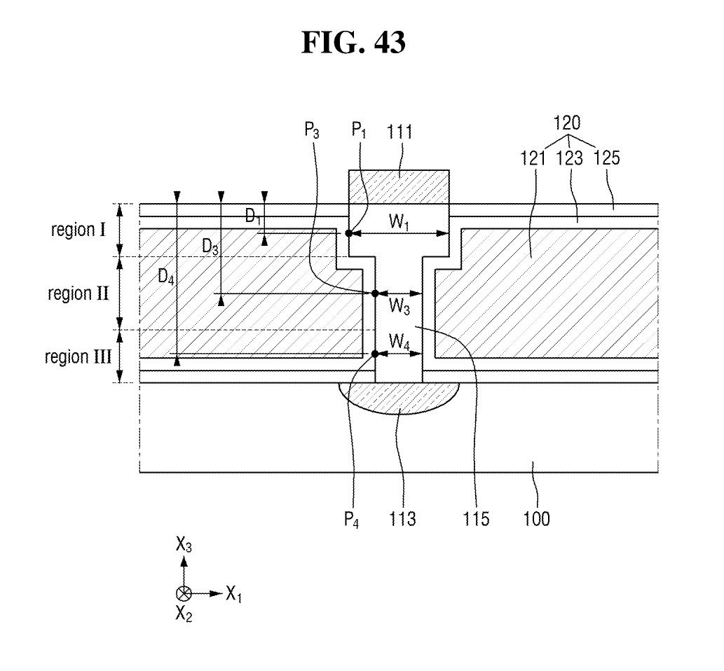

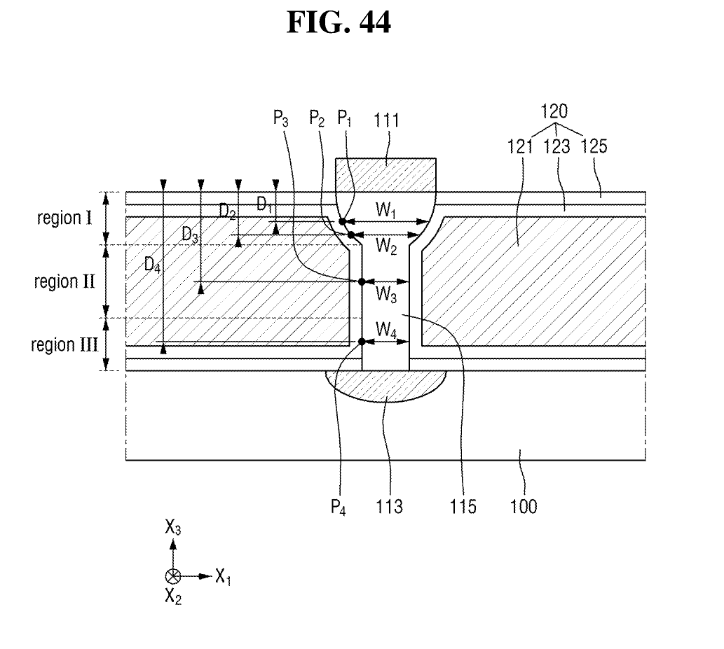

Hereinafter, a semiconductor device according to exemplary embodiments will be described with reference to FIGS. 42 to 44. For clarity of illustration, the redundant description will be omitted.

FIGS. 42 to 44 are cross-sectional views of a semiconductor device according to exemplary embodiments.

Referring to FIGS. 42 to 44, a source region 113 may be formed in a substrate 100.

The semiconductor pattern 115 may be formed on the substrate 100 and may be extended in the third direction X3. Region II of the semiconductor pattern 115 may be disposed between the substrate 100 and region I. Region III of the semiconductor pattern 115 may be disposed between region II and the substrate 100.

The semiconductor pattern 115 may have a wire shape, for example.

A drain region 111 may be formed on the semiconductor pattern 115. For example, the drain region 111 may be formed on region I of the semiconductor pattern 115. The region I may be disposed between the drain region 111 and region II.

A gate structure 120 may surround the semiconductor pattern 115. For example, the semiconductor pattern 115 may penetrate the gate structure 120. The gate electrode 121 may intersect region II of the semiconductor pattern 115. That is, the gate electrode 121 may surround region II of the semiconductor pattern 115. A gate spacer 125 may be formed between the substrate 100 and the gate electrode 121.

Thickness of each portion of the semiconductor pattern 115 may be measured in the first direction X1. The first direction X1 may intersect the direction in which the semiconductor pattern 115 is extended, for example. However, this is not limited thereto. For example, the thickness of each portion of the semiconductor pattern 115 may be the diameter of the semiconductor pattern 115. Alternatively, the thickness of each portion of the semiconductor pattern 115 may be an average of diameters at positions spaced apart from the drain region 111 by predetermined distances.

Although the semiconductor patterns 115 included in the semiconductor device according to exemplary embodiments have been described with reference to the accompanying drawings, the shapes of the semiconductor patterns 115 are not limited thereto. For example, the semiconductor pattern 115 may have a shape that the thickness W1 of region I of the semiconductor pattern 115 is substantially equal to or larger than the thickness W4 of region III. Alternatively, the semiconductor pattern 115 may have a shape that the thickness W1 of region I of the semiconductor pattern 115 is larger than the thickness W3 of region II.

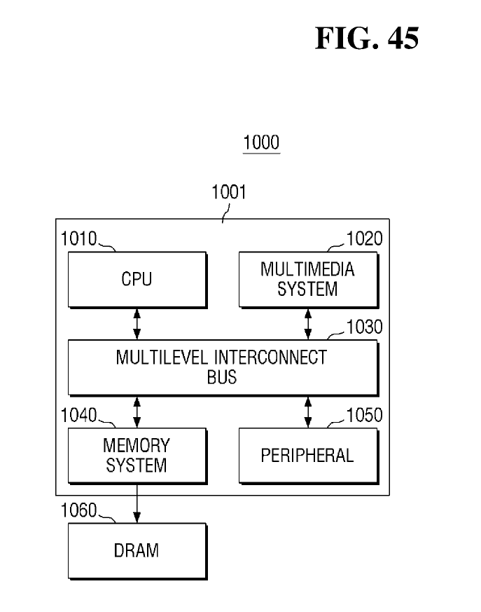

FIG. 45 is a block diagram of a system on chip (SoC) system including a semiconductor device according to exemplary embodiments.

Referring to FIG. 45, the SoC system 1000 may include an application processor 1001 and a DRAM 1060.

The application processor 1001 may include a central processing unit (CPU) 1010, a multimedia system 1020, a bus 1030, a memory system 1040 and a peripheral 1050.

The CPU 1010 may perform operations necessary for driving the SoC system 1000. In some exemplary embodiments, the CPU 1010 may be configured in a multi-core environment including multiple cores.

The multimedia system 1020 may be used in the SoC system 1000 for performing various types of multimedia functions. The multimedia system 1020 may include a 3D engine module, video codec, a display system, a camera system, a post-processor, etc.

The bus 1030 may be used for data communications among the CPU 1010, the multimedia system 1020, the memory system 1040 and the peripheral 1050. In exemplary embodiments, the bus 1030 may have a multi-layer structure. Specifically, examples of the bus 1030 may include, but are not limited thereto, a multi-layer AHB (Advanced High-performance Bus) and a multi-layer AXI (Advanced eXtensible Interface), for example.

The memory system 1040 may provide the application processor 1001 with an environment necessary for high speed operation with an external memory (e.g., the DRAM 1060). In some exemplary embodiments, the memory system 1040 may include an additional controller (e.g., a DRAM controller) for controlling the external memory (e.g., the DRAM 1060).

The peripheral 1050 may provide an environment necessary for facilitating the connection between the SoC system 1000 and an external device (e.g., a main board). Accordingly, the peripheral 1050 may have various interfaces that make external devices connected to the SoC system 1000 compatible with the system.

The DRAM 1060 may work as an operational memory necessary for the application processor 1001 to operate. In some exemplary embodiments, the DRAM 1060 may be disposed outside the application processor 1001, as shown in FIG. 45. Specifically, the DRAM 1060 may be packaged with the application processor 1001 as a package-on-package (PoP) assembly.

At least one of the elements of the SoC system 1000 may include at least one semiconductor device according to the above-described exemplary embodiments.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the exemplary embodiments be considered in all respects as illustrative and not restrictive, reference being made to the appended claims rather than the foregoing description to indicate the scope of the inventive concept.

What is claimed is:

1. A semiconductor device comprising:
a drain region and a source region spaced apart from each other;
a semiconductor pattern disposed between the drain region and the source region and comprising a first region and a second region, wherein a thickness of the first region is larger than a thickness of the second region, and the first region is disposed between the drain region and the second region; and
a gate electrode intersecting the semiconductor pattern.

2. The semiconductor device of claim 1, wherein the first region of the semiconductor pattern comprises a first position spaced apart from the drain region by a first distance and a second position spaced apart from the drain region by a second distance larger than the first distance, and
wherein a thickness of the first region of the semiconductor pattern at the first position is larger than a thickness of the first region of the semiconductor pattern at the second position.

3. The semiconductor device of claim 1, wherein the semiconductor pattern further comprises a third region, and
wherein the second region of the semiconductor pattern is disposed between the first region of the semiconductor pattern and the third region of the semiconductor pattern.

4. The semiconductor device of claim 3, wherein the third region of the semiconductor pattern comprises a fourth position spaced apart from the drain region by a fourth distance and a fifth position spaced apart from the drain region by a fifth distance larger than the fourth distance, and
wherein a thickness of the third region of the semiconductor pattern at the fourth position is smaller than a thickness of the third region of the semiconductor pattern at the fifth position.

5. The semiconductor device of claim 3, wherein a thickness of the third region of the semiconductor pattern is smaller than the thickness of the first region of the semiconductor pattern.

6. The semiconductor device of claim 3, wherein a thickness of the third region of the semiconductor pattern is substantially equal to the thickness of the second region of the semiconductor pattern.

7. The semiconductor device of claim 1, wherein:
the first region of the semiconductor pattern comprises a first position spaced apart from the drain region by a first distance,
the second region of the semiconductor pattern comprises a third position spaced apart from the drain region by a third distance larger than the first distance,
the thickness of the first region of the semiconductor pattern is measured at the first position, and
the thickness of the second region of the semiconductor pattern is measured at the third position.

8. The semiconductor device of claim 1, further comprising:
a substrate,
wherein the semiconductor pattern is formed above the substrate with spacing therebetween, and
wherein a part of the gate electrode is disposed between the semiconductor pattern and the substrate.

9. The semiconductor device of claim 1, further comprising:
a substrate,
wherein the semiconductor pattern comprises a first semiconductor pattern and a second semiconductor pattern, each formed above the substrate with spacing therebetween,
wherein the first semiconductor pattern is spaced apart from the second semiconductor pattern, and
wherein a part of the gate electrode is disposed between the first semiconductor pattern and the second semiconductor pattern and another part of the gate electrode is disposed between the second semiconductor pattern and the substrate.

10. The semiconductor device of claim 1, wherein:
the semiconductor pattern is formed on a substrate,
the source region is formed in the substrate,
the second region of the semiconductor pattern is disposed between the substrate and the first region of the semiconductor pattern, and
the thickness of the first region of the semiconductor pattern and the thickness of the second region of the semiconductor pattern are measured in a direction intersecting a direction in which the semiconductor pattern is extended.

11. A semiconductor device comprising:
a substrate;
a field insulation film on the substrate;
a semiconductor pattern protruding from the substrate and comprising a first region and a second region, wherein a part of the semiconductor pattern protrudes from an upper surface of the field insulation film;
a source region and a drain region disposed on the substrate and on both sides of the semiconductor pattern, respectively; and
a gate electrode intersecting the semiconductor pattern,
wherein the first region of the semiconductor pattern is disposed between the drain region and the second region, and
a thickness of the first region of the semiconductor pattern is larger than a thickness of the second region of the semiconductor pattern.

12. The semiconductor device of claim 11, wherein the semiconductor pattern is extended in a first direction,
the gate electrode is extended in a second direction different from the first direction, and
a thickness of the first region and a thickness of the second region are measured in the second direction.

13. The semiconductor device of claim 11, wherein the first region of the semiconductor pattern comprises a first position spaced apart from the drain region by a first distance and a second position spaced apart from the drain region by a second distance larger than the first distance, and
wherein a thickness of the first region of the semiconductor pattern at the first position is larger than a thickness of the first region of the semiconductor pattern at the second position.

14. The semiconductor device of claim 11, wherein the first region of the semiconductor pattern comprises a first position spaced apart from the drain region by a first distance,
the second region of the semiconductor pattern comprises a third position spaced apart from the drain region by a third distance larger than the first distance,
the thickness of the first region of the semiconductor pattern is measured at the first position, and
the thickness of the second region of the semiconductor pattern is measured at the third position.

15. The semiconductor device of claim 11, wherein the substrate comprises a base substrate and a buried oxide film on the base substrate,
the semiconductor pattern is formed on the buried oxide film, and
the thickness of the first region of the semiconductor pattern and the thickness of the second region of the semiconductor pattern are measured in a direction perpendicular to the substrate.

16. A semiconductor device comprising:
a drain region and a source region spaced apart from each other;
a channel region disposed between the drain region and the source region; and
a gate electrode intersecting the channel region,
wherein a thickness of a region of the channel region adjacent to the drain region is larger than a thickness of a region of the channel region adjacent to the source region.

17. The semiconductor device of claim 16, wherein the channel region comprises a semiconductor pattern comprising a first region and a second region.

18. The semiconductor device of claim 17, wherein the channel region further comprises a third region, and
wherein the second region is disposed between the first region and the third region.

19. The semiconductor device of claim 18, wherein a thickness of the third region is smaller than the thickness of the first region.

20. The semiconductor device of claim 18, wherein a thickness of the third region is substantially equal to the thickness of the second region.
